(19) United States
(12) Patent Application Publication
(10) Pub. No.: US 2025/0031506 A1
(43) Pub. Date: Jan. 23, 2025

(54) DISPLAY APPARATUS USING SEMICONDUCTOR LIGHT-EMITTING DEVICE, AND MANUFACTURING METHOD THEREFOR

(71) Applicant: LG ELECTRONICS INC., Seoul (KR)

(72) Inventors: Taehoon KIM, Seoul (KR); Byungjoon RHEE, Seoul (KR); Hwanjoon CHOI, Seoul (KR)

(73) Assignee: LG ELECTRONICS INC., Seoul (KR)

(21) Appl. No.: 18/716,047

(22) PCT Filed: Jan. 27, 2022
(86) PCT No.: PCT/KR2022/001493

§ 371 Date: Jun. 3, 2024

(51) Int. Cl. H01L 33/62; H01L 23/00; H01L 25/16

(52) U.S. Cl. CPC H01L 33/62; H01L 24/05; H01L 24/08; H01L 25/167; H01L 2224/05571; H01L 2224/05573; H01L 2224/0569; H01L 2224/08501; H01L 2933/0066

(57) ABSTRACT

The present invention relates to a display apparatus using, for example, a micro light emitting diode (LED), and a manufacturing method therefor, wherein the apparatus and method can be applied to a technical field related to display apparatuses. In order to achieve the above objective, a display apparatus according to an embodiment of the present invention comprises: a substrate on which a plurality of unit pixel areas are defined; a wiring electrode positioned on the substrate and positioned in each of the unit pixel areas; a light emitting device that has a device electrode electrically connected to the wiring electrode and is assembled in each of the unit pixel areas; and a coupling forming portion providing a coupling force by which the light emitting device is coupled to the unit pixel areas, wherein the coupling forming portion comprises: an active portion coupled to the light emitting device; and a coupling portion which forms a chemical bond with the active portion and is patterned on the substrate.

### TECHNICAL FIELD

The present disclosure is applicable to a display related technical field and, for example, relates to a display apparatus using a micro Light Emitting Diode (LED) and fabricating method thereof.

### BACKGROUND ART

Recently, a display apparatus having excellent characteristics such as thin, flexible, and the like has been developed in the field of display technology. On the other hand, currently commercialized main displays are represented by a Liquid Crystal Display (LCD) and an Active Matrix Organic Light Emitting Diode (AMOLED) display.

Meanwhile, a Light Emitting Diode (LED) is a well-known semiconductor light emitting device that converts a current into light, and has been used as an image display light source of an electronic device as well as an information communication device along with a GaP:N-based green LED and since the commercialization of a red LED that uses GaAsP compound semiconductors in 1962. Therefore, a method for solving the above-described problem may be presented by implementing a flexible display using the semiconductor light-emitting device.

Recently, as such a Light Emitting Diode (LED) tends to have a small size, it is fabricated as a micrometer-sized LED (micro LED) to be used as a pixel of a display apparatus. Such a micro LED is transferred onto a substrate in various ways.

A recent issue regarding micro LEDs is the technology of transferring LEDs to a panel. Many LEDs are used to make one display apparatus using micro LEDs, and it is very difficult and time-consuming to make them one by one.

As described above, in the case of an optical device or a display panel using a micro LED, a process of transferring a micro LED from an LED wafer to a wiring substrate and forming an electrical connection with the wiring substrate is required.

Generally, in the case of a transfer process, an LED chip array formed on an LED wafer is selectively separated into a temporary substrate at a specific interval and then transferred to a final wiring substrate. Such a transfer process may be classified into a stamp transfer, a fluid assembly, a transfer technique using an ultrasonic wave or a laser, or the like according to a detailed application method.

Among them, the fluid assembly is advantageous in terms of productivity per hour and LED selection irrespective of an area compared to other transfer technologies. However, there remains a problem that has to be solved yet in terms of process reliability and yield.

In particular, for the implementation of three colors of red, green, and blue pixels for each pixel, known is a method of fabricating LEDs in different shapes or structures for each color so that the LEDs of the three colors are selectively assembled at designated positions on a wiring substrate and forming a mounting portion (hole) with a corresponding shape so that the LEDs can be assembled on the wiring substrate.

In addition, a technique of finely adjusting a size and frequency of an electric field is applied so that LED in fluid is uniformly distributed and effectively aligned in all areas of a wiring substrate. However, since the LED is simply assembled to a mounting portion until the LED is directly bonded to the wiring substrate, defects such as rotation and double assembly of the LED may occur according to the fluid flow (movement).

In particular, in order to assemble an LED on a non-assembled mounting portion on a wiring substrate, an LED that is already assembled in the course of repeatedly moving a multitude of LEDs to the corresponding portion but is not bonded to the wiring substrate may escape from the mounting portion to cause defective pixels. For high resolution applications, a size of an LED chip and a pitch between pixels are reduced and electric field interference between the assembly areas occurs, thereby further increasing the occurrence of the defective pixels described above.

An increase in the defective pixels leads to an increase in process difficulty due to an increase in the number of processes for resolving the defects (i.e., repair), additional generation of process costs, and degradation of productivity.

Therefore, there is a need for an effective transfer technique capable of solving such a problem.

### DISCLOSURE

### Technical Tasks

One technical task of the present disclosure is to provide a display apparatus using a light emitting device and fabricating method thereof, thereby stably and efficiently assembling and transferring a light emitting device to a wiring substrate.

Another technical task of the present disclosure is to provide a display apparatus using a light emitting device and fabricating method thereof, thereby reducing a probability that a defect will occur when the light emitting device is assembled and transferred to a wiring substrate.

Another technical task of the present disclosure is to provide a display apparatus using a light emitting device and fabricating method thereof, thereby assembling and transferring the light emitting device onto a wiring substrate through molecular recognition such as chemical interaction, antigen-antibody interaction, and the like.

Further technical task of the present disclosure is to provide a display apparatus using a light emitting device and fabricating method thereof, thereby assembling and transferring the light emitting device selectively to a wiring substrate.

### Technical Solutions

In a first technical aspect of the present disclosure, provided is a display apparatus including a substrate having a multitude of unit pixel areas defined thereon, a wiring electrode located in each of the unit pixel areas on the substrate, a light emitting device assembled in each of the unit pixel areas by electrically connecting a device electrode to the wiring electrode, and a bonding formation part providing a bonding strength for coupling the light emitting device to the unit pixel area, the bonding formation part including an active part bonded to the light emitting device; and a bonding part chemically bonded to the active part and patterned on the substrate.

The active part may include a first compound and the bonding part may include a second compound bonded to the first compound.

At least one of the first compound or the second compound may be bonded to the light emitting device or the substrate by a polymer chain structure.

A bond length of the polymer chain structure may be adjusted according to an external condition.

The polymer chain structure may include at least one of a temperature-sensitive polymer or a pH-sensitive functional group.

The polymer chain structure may include a dendrimer type polymer chain structure or a monomer including at least one of ethylene glycol, propylene glycol, or propylene imine.

The first compound and the second compound may be bonded by molecular recognition bonding including a host-guest interaction or an antigen-antibody interaction.

The first compound may include at least one of a guest material or an antigen material including one of an aromatic compound and a monosaccharide compound.

The second compound may include a host material of a macrocyclic compound or an antibody material capable of bonding to the antigen material as a functional group capable of bonding by forming a pair with the first compound.

The bonding formation part may include a different compound according to a color of a pixel of the unit pixel area.

The wiring electrode may include a metal pad in a donut shape and wherein the bonding part is located inside the donut shape.

In a second technical aspect of the present disclosure, provided is a method of fabricating a display apparatus using a light emitting device, the method including introducing a bonding formation part for assembling the light emitting device to a unit device area on a wiring substrate based on a chemical bond, assembling the light emitting device to the unit device area based on a bonding strength by the bonding formation part in a fluid, and electrically connecting the light emitting device to a wiring of the wiring substrate.

The introducing the bonding formation part may include introducing a first compound to the light emitting device and introducing a second compound to the unit device area.

The assembling the light emitting device to the unit device area may include reducing a bond length of the bonding formation part.

### Advantageous Effects

According to a display apparatus and fabricating method thereof according to an embodiment of the present disclosure, a light source may be provided in a completed form of a light emitting device chip for stable and efficient fluid assembly by adding a simple process step without changing an existing light emitting device chip process.

In addition, a shape of the light emitting device chip provided in this form may reduce a defect assembly probability such as double assembly, detachment after assembly, and the like, which may be an issue in a fluid assembly method.

In addition, since a light emitting device chip adjacent to a designated position is easily assembled, a complicated series of process steps for precisely adjusting a size and frequency of an electric field for dispersing and moving a light emitting device may be omitted, thereby improving productivity.

In addition, when the present disclosure is used, a light emitting device is assembled to a wiring substrate based on chemical bonding, thereby increasing assembly stability.

In addition, it is also possible to selectively transfer a light emitting device when the paired compound is separated and introduced into the light emitting device and a wiring substrate.

### DESCRIPTION OF DRAWINGS

FIG. 1 is a conceptual diagram illustrating an example of a display apparatus using a semiconductor light emitting device of the present disclosure.

FIG. 2 is an enlarged diagram of a portion A of FIG. 1.

FIG. 3A and FIG. 3B are cross-sectional diagrams taken along lines B-B and C-C of FIG. 2.

FIG. 4 is a conceptual diagram illustrating a flip chip type semiconductor light emitting device of FIG. 3.

FIGS. 5A to 5C are conceptual diagrams illustrating various types for implementing colors in relation to a flip chip type semiconductor light emitting device.

FIG. 6 is a cross-sectional diagram illustrating an example of a method of fabricating a display apparatus using a semiconductor light emitting device of the present disclosure.

FIG. 7 is a perspective diagram illustrating another example of a display apparatus using a semiconductor light emitting device of the present disclosure.

FIG. 8 is a cross-sectional diagram taken along line D-D of FIG. 7.

FIG. 9 is a conceptual diagram illustrating a vertical semiconductor light emitting device of FIG. 8.

FIG. 10 is a schematic cross-sectional diagram illustrating a display apparatus using a light emitting device according to an embodiment of the present disclosure.

FIG. 11 is a diagram illustrating an example of a vertical light emitting device usable in a display apparatus using a light emitting device according to an embodiment of the present disclosure.

FIG. 12 is a diagram illustrating a state in which an active part is introduced into the vertical light emitting device of FIG. 11.

FIG. 13 is a schematic diagram illustrating an example of an active part that may be used in a display apparatus using a light emitting device according to an embodiment of the present disclosure.

FIG. 14 is a schematic diagram illustrating another example of an active part usable in a display apparatus using a light emitting device according to an embodiment of the present disclosure.

FIG. 15 is a diagram illustrating an example of a horizontal light emitting device usable in a display apparatus using a light emitting device according to an embodiment of the present disclosure.

FIG. 16 is a view illustrating a state in which an active part is introduced into the horizontal light emitting device of FIG. 15.

FIG. 17 is a diagram illustrating another example of a horizontal light emitting device usable in a display apparatus using a light emitting device according to an embodiment of the present disclosure.

FIG. 18 is diagram illustrating a state in which an active part is introduced into the horizontal light emitting device of FIG. 17.

FIGS. 19 to 21 are diagrams illustrating a process of fabricating a display apparatus using a light emitting device according to a first embodiment of the present disclosure.

FIGS. 22 to 24 are diagrams illustrating a process of fabricating a display apparatus using a light emitting device according to a second embodiment of the present disclosure.

FIG. 25 is a schematic diagram illustrating an example of a bonding part usable in a display apparatus using a light emitting device according to an embodiment of the present disclosure.

FIG. 26 is a schematic diagram illustrating another example of a bonding part usable in a display apparatus using a light emitting device according to an embodiment of the present disclosure.

FIGS. 27 to 32 are diagrams illustrating an assembly process of a vertical light emitting device in a display apparatus using a light emitting device according to an embodiment of the present disclosure.

FIGS. 33 to 36 are diagrams illustrating an assembly process of a horizontal light emitting device in a display apparatus using a light emitting device according to an embodiment of the present disclosure.

FIG. 37 is a flowchart illustrating a method of fabricating a display apparatus using a light emitting device according to an embodiment of the present disclosure.

FIG. 38 is a conceptual diagram illustrating a specific example of a polymer chain structure used in a display apparatus using a light emitting device according to an embodiment of the present disclosure.

FIG. 39 and FIG. 40 are diagrams illustrating a state of having selectivity for each color of a pixel in a display apparatus using a light emitting device according to an embodiment of the present disclosure.

FIG. 41 is a conceptual diagram illustrating an example in which a different bonding formation part is formed for each light emitting device color.

### BEST MODE

Reference will now be made in detail to embodiments of the present disclosure, examples of which are illustrated in the accompanying drawings. Wherever possible, the same reference numbers will be used throughout the drawings to refer to the same or like parts, and a redundant description thereof will be omitted. As used herein, the suffixes “module” and “unit” are added or used interchangeably to facilitate preparation of this specification, and are not intended to suggest distinct meanings or functions. In describing embodiments disclosed in this specification, relevant well-known technologies may not be described in detail in order to avoid obscuring the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining two or more drawings are also within the scope of the present disclosure.

In addition, when an element such as a layer, a region, or a substrate is described as being “on” another element, it is to be understood that the element may be directly on the other element, or there may be an intermediate element between them.

The display device described herein conceptually includes all display devices that display information with a unit pixel or a set of unit pixels. Therefore, the term “display device” may be applied not only to finished products but also to parts. For example, a panel corresponding to a part of a digital TV also independently corresponds to the display device in the present specification. Such finished products include a mobile phone, a smartphone, a laptop computer, a digital broadcasting terminal, a personal digital assistant (PDA), a portable multimedia player (PMP), a navigation system, a slate PC, a tablet PC, an Ultrabook, a digital TV, a desktop computer, and the like.

However, it will be readily apparent to those skilled in the art that the configuration according to the embodiments described herein is also applicable to new products to be developed later as display devices.

In addition, the term “semiconductor light-emitting element” mentioned in this specification conceptually includes an LED, a micro LED, and the like, and may be used interchangeably therewith.

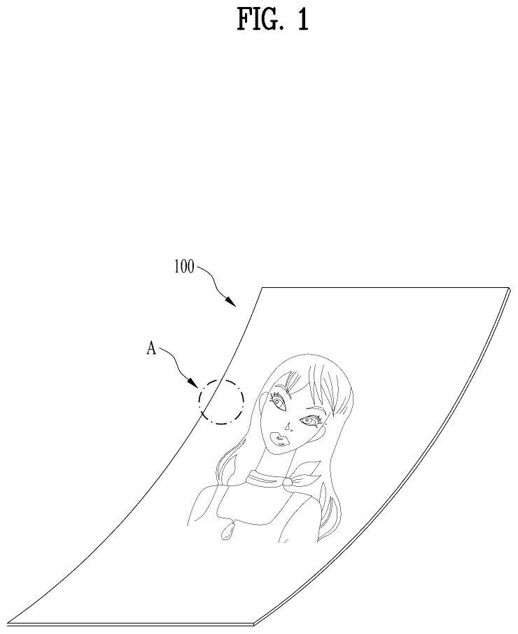

FIG. 1 is a conceptual view illustrating an embodiment of a display device using a semiconductor light emitting element according to the present disclosure.

As shown in FIG. 1, information processed by a controller (not shown) of a display device 100 may be displayed using a flexible display.

The flexible display may include, for example, a display that can be warped, bent, twisted, folded, or rolled by external force.

Furthermore, the flexible display may be, for example, a display manufactured on a thin and flexible substrate that can be warped, bent, folded, or rolled like paper while maintaining the display characteristics of a conventional flat panel display.

When the flexible display remains in an unbent state (e.g., a state having an infinite radius of curvature) (hereinafter referred to as a first state), the display area of the flexible display forms a flat surface. When the display in the first sate is changed to a bent state (e.g., a state having a finite radius of curvature) (hereinafter referred to as a second state) by external force, the display area may be a curved surface. As shown in FIG. 1, the information displayed in the second state may be visual information output on a curved surface. Such visual information may be implemented by independently controlling the light emission of subpixels arranged in a matrix form. The unit pixel may mean, for example, a minimum unit for implementing one color.

The unit pixel of the flexible display may be implemented by a semiconductor light emitting element. In the present disclosure, a light emitting diode (LED) is exemplified as a type of the semiconductor light emitting element configured to convert electric current into light. The LED may be formed in a small size, and may thus serve as a unit pixel even in the second state.

Hereinafter, a flexible display implemented using the LED will be described in more detail with reference to the drawings.

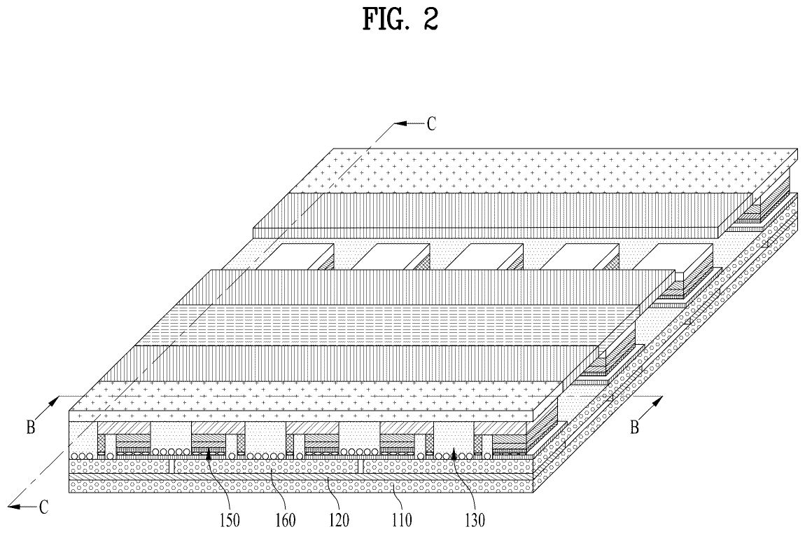

FIG. 2 is a partially enlarged view showing part A of FIG. 1.

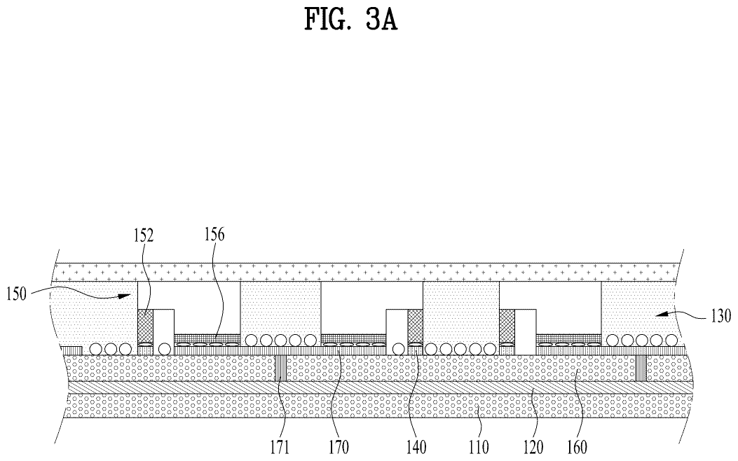

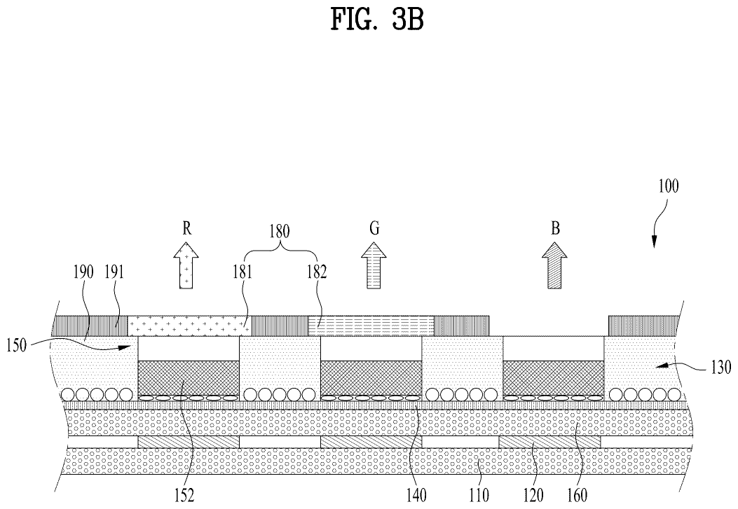

FIGS. 3A and 3B are cross-sectional views taken along lines B-B and C-C in FIG. 2.

As shown in FIGS. 2, 3A and 3B, the display device 100 using a passive matrix (PM) type semiconductor light emitting element is exemplified as the display device 100 using a semiconductor light emitting element. However, the examples described below are also applicable to an active matrix (AM) type semiconductor light emitting element.

The display device 100 may include a substrate 110, a first electrode 120, a conductive adhesive layer 130, a second electrode 140, and at least one semiconductor light emitting element 150, as shown in FIG. 2.

The substrate 110 may be a flexible substrate. For example, to implement a flexible display device, the substrate 110 may include glass or polyimide (PI). Any insulative and flexible material such as polyethylene naphthalate (PEN) or polyethylene terephthalate (PET) may be employed. In addition, the substrate 110 may be formed of either a transparent material or an opaque material.

The substrate 110 may be a wiring substrate on which the first electrode 120 is disposed. Thus, the first electrode 120 may be positioned on the substrate 110.

As shown in FIG. 3A, an insulating layer 160 may be disposed on the substrate 110 on which the first electrode 120 is positioned, and an auxiliary electrode 170 may be positioned on the insulating layer 160. In this case, a stack in which the insulating layer 160 is laminated on the substrate 110 may be a single wiring substrate. More specifically, the insulating layer 160 may be formed of an insulative and flexible material such as PI, PET, or PEN, and may be integrated with the substrate 110 to form a single substrate.

The auxiliary electrode 170, which is an electrode that electrically connects the first electrode 120 and the semiconductor light emitting element 150, is positioned on the insulating layer 160, and is disposed to correspond to the position of the first electrode 120. For example, the auxiliary electrode 170 may have a dot shape and may be electrically connected to the first electrode 120 by an electrode hole 171 formed through the insulating layer 160. The electrode hole 171 may be formed by filling a via hole with a conductive material.

As shown in FIG. 2 or 3A, a conductive adhesive layer 130 may be formed on one surface of the insulating layer 160, but embodiments of the present disclosure are not limited thereto. For example, a layer performing a specific function may be formed between the insulating layer 160 and the conductive adhesive layer 130, or the conductive adhesive layer 130 may be disposed on the substrate 110 without the insulating layer 160. In a structure in which the conductive adhesive layer 130 is disposed on the substrate 110, the conductive adhesive layer 130 may serve as an insulating layer.

The conductive adhesive layer 130 may be a layer having adhesiveness and conductivity. For this purpose, a material having conductivity and a material having adhesiveness may be mixed in the conductive adhesive layer 130. In addition, the conductive adhesive layer 130 may have ductility, thereby providing making the display device flexible.

As an example, the conductive adhesive layer 130 may be an anisotropic conductive film (ACF), an anisotropic conductive paste, a solution containing conductive particles, or the like. The conductive adhesive layer 130 may be configured as a layer that allows electrical interconnection in the direction of the Z-axis extending through the thickness, but is electrically insulative in the horizontal X-Y direction. Accordingly, the conductive adhesive layer 130 may be referred to as a Z-axis conductive layer (hereinafter, referred to simply as a “conductive adhesive layer”).

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

The ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

Referring back to FIG. 3A, the second electrode 140 is positioned on the insulating layer 160 and spaced apart from the auxiliary electrode 170. That is, the conductive adhesive layer 130 is disposed on the insulating layer 160 having the auxiliary electrode 170 and the second electrode 140 positioned thereon.

After the conductive adhesive layer 130 is formed with the auxiliary electrode 170 and the second electrode 140 positioned on the insulating layer 160, the semiconductor light emitting element 150 is connected thereto in a flip-chip form by applying heat and pressure. Thereby, the semiconductor light emitting element 150 is electrically connected to the first electrode 120 and the second electrode 140.

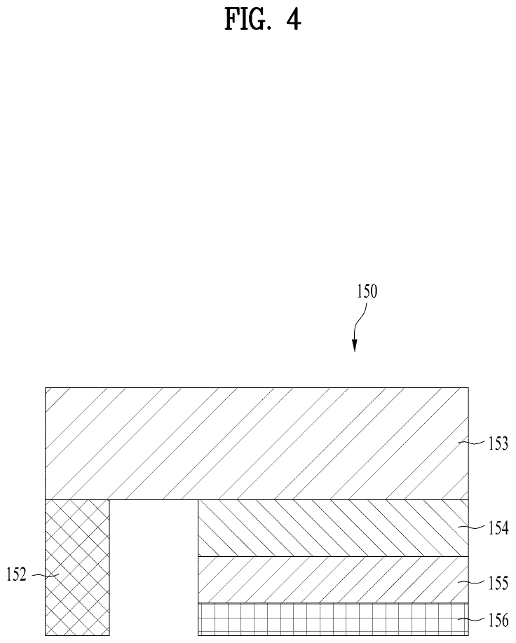

FIG. 4 is a conceptual view illustrating the flip-chip type semiconductor light emitting element of FIG. 3.

Referring to FIG. 4, the semiconductor light emitting element may be a flip chip-type light emitting device.

For example, the semiconductor light emitting element may include a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 disposed on the n-type semiconductor layer 153 and horizontally spaced apart from the p-type electrode 156. In this case, the p-type electrode 156 may be electrically connected to the auxiliary electrode 170, which is shown in FIG. 3, by the conductive adhesive layer 130, and the n-type electrode 152 may be electrically connected to the second electrode 140.

Referring back to FIGS. 2, 3A and 3B, the auxiliary electrode 170 may be elongated in one direction. Thus, one auxiliary electrode may be electrically connected to the plurality of semiconductor light emitting elements 150. For example, p-type electrodes of semiconductor light emitting elements on left and right sides of an auxiliary electrode may be electrically connected to one auxiliary electrode.

More specifically, the semiconductor light emitting element 150 may be press-fitted into the conductive adhesive layer 130 by heat and pressure. Thereby, only the portions of the semiconductor light emitting element 150 between the p-type electrode 156 and the auxiliary electrode 170 and between the n-type electrode 152 and the second electrode 140 may exhibit conductivity, and the other portions of the semiconductor light emitting element 150 do not exhibit conductivity as they are not press-fitted. In this way, the conductive adhesive layer 130 interconnects and electrically connects the semiconductor light emitting element 150 and the auxiliary electrode 170 and interconnects and electrically connects the semiconductor light emitting element 150 and the second electrode 140.

The plurality of semiconductor light emitting elements 150 may constitute a light emitting device array, and a phosphor conversion layer 180 may be formed on the light emitting device array.

The light emitting device array may include a plurality of semiconductor light emitting elements having different luminance values. Each semiconductor light emitting element 150 may constitute a unit pixel and may be electrically connected to the first electrode 120. For example, a plurality of first electrodes 120 may be provided, and the semiconductor light emitting elements may be arranged in, for example, several columns. The semiconductor light emitting elements in each column may be electrically connected to any one of the plurality of first electrodes.

In addition, since the semiconductor light emitting elements are connected in a flip-chip form, semiconductor light emitting elements grown on a transparent dielectric substrate may be used. The semiconductor light emitting elements may be, for example, nitride semiconductor light emitting elements. Since the semiconductor light emitting element 150 has excellent luminance, it may constitute an individual unit pixel even when it has a small size.

As shown in FIGS. 3A and 3B, a partition wall 190 may be formed between the semiconductor light emitting elements 150. In this case, the partition wall 190 may serve to separate individual unit pixels from each other, and may be integrated with the conductive adhesive layer 130. For example, by inserting the semiconductor light emitting element 150 into the ACF, the base member of the ACF may form the partition wall.

In addition, when the base member of the ACF is black, the partition wall 190 may have reflectance and increase contrast even without a separate black insulator.

As another example, a reflective partition wall may be separately provided as the partition wall 190. In this case, the partition wall 190 may include a black or white insulator depending on the purpose of the display device. When a partition wall including a white insulator is used, reflectivity may be increased. When a partition wall including a black insulator is used, it may have reflectance and increase contrast.

The phosphor conversion layer 180 may be positioned on the outer surface of the semiconductor light emitting element 150. For example, the semiconductor light emitting element 150 may be a blue semiconductor light emitting element that emits blue (B) light, and the phosphor conversion layer 180 may function to convert the blue (B) light into a color of a unit pixel. The phosphor conversion layer 180 may be a red phosphor 181 or a green phosphor 182 constituting an individual pixel.

That is, the red phosphor 181 capable of converting blue light into red (R) light may be laminated on a blue semiconductor light emitting element at a position of a unit pixel of red color, and the green phosphor 182 capable of converting blue light into green (G) light may be laminated on the blue semiconductor light emitting element at a position of a unit pixel of green color. Only the blue semiconductor light emitting element may be used alone in the portion constituting the unit pixel of blue color. In this case, unit pixels of red (R), green (G), and blue (B) may constitute one pixel. More specifically, a phosphor of one color may be laminated along each line of the first electrode 120. Accordingly, one line on the first electrode 120 may be an electrode for controlling one color. That is, red (R), green (G), and blue (B) may be sequentially disposed along the second electrode 140, thereby implementing a unit pixel.

However, embodiments of the present disclosure are not limited thereto. Unit pixels of red (R), green (G), and blue (B) may be implemented by combining the semiconductor light emitting element 150 and the quantum dot (QD) rather than using the phosphor.

Also, a black matrix 191 may be disposed between the phosphor conversion layers to improve contrast. That is, the black matrix 191 may improve contrast of light and darkness.

However, embodiments of the present disclosure are not limited thereto, and anther structure may be applied to implement blue, red, and green colors.

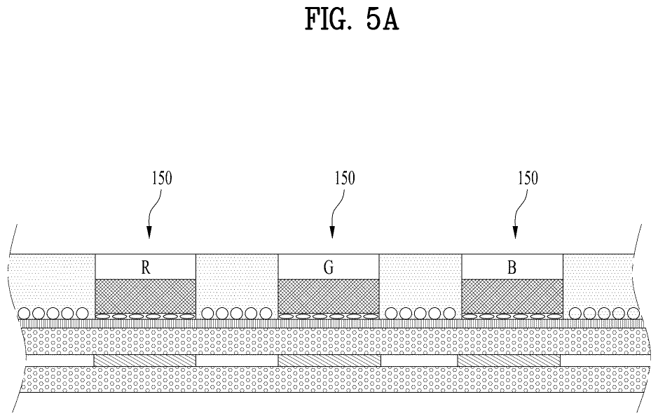

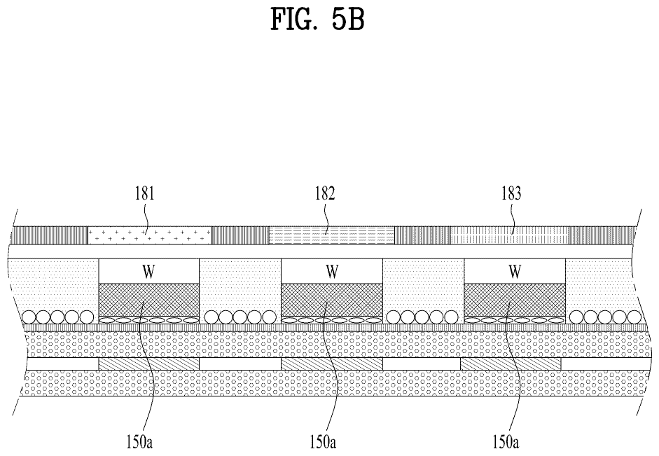

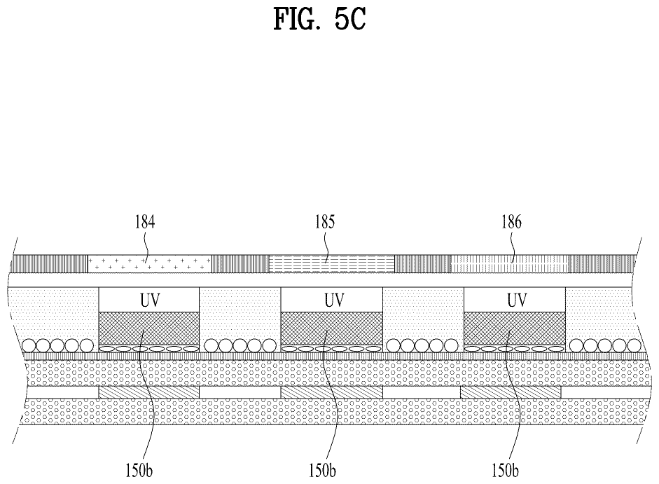

FIGS. 5A to 5C are conceptual views illustrating various examples of implementation of colors in relation to a flip-chip type semiconductor light emitting element.

Referring to FIG. 5A, each semiconductor light emitting element may be implemented as a high-power light emitting device emitting light of various colors including blue by using gallium nitride (GaN) as a main material and adding indium (In) and/or aluminum (Al).

In this case, each semiconductor light emitting element may be a red, green, or blue semiconductor light emitting element to form a unit pixel (subpixel). For example, red, green, and blue semiconductor light emitting elements R, G, and B may be alternately disposed, and unit pixels of red, green, and blue may constitute one pixel by the red, green and blue semiconductor light emitting elements. Thereby, a full-color display may be implemented.

Referring to FIG. 5B, the semiconductor light emitting element 150a may include a white light emitting device W having a yellow phosphor conversion layer, which is provided for each device. In this case, in order to form a unit pixel, a red phosphor conversion layer 181, a green phosphor conversion layer 182, and a blue phosphor conversion layer 183 may be disposed on the white light emitting device W. In addition, a unit pixel may be formed using a color filter repeating red, green, and blue on the white light emitting device W.

Referring to FIG. 5C, a red phosphor conversion layer 181, a green phosphor conversion layer 185, and a blue phosphor conversion layer 183 may be provided on a ultraviolet light emitting device. Not only visible light but also ultraviolet (UV) light may be used in the entire region of the semiconductor light emitting element. In an embodiment, UV may be used as an excitation source of the upper phosphor in the semiconductor light emitting element.

Referring back to this example, the semiconductor light emitting element is positioned on the conductive adhesive layer to constitute a unit pixel in the display device. Since the semiconductor light emitting element has excellent luminance, individual unit pixels may be configured despite even when the semiconductor light emitting element has a small size.

Regarding the size of such an individual semiconductor light emitting element, the length of each side of the device may be, for example, 80 μm or less, and the device may have a rectangular or square shape. When the semiconductor light emitting element has a rectangular shape, the size thereof may be less than or equal to 20 μm×80 μm.

In addition, even when a square semiconductor light emitting element having a side length of 10 μm is used as a unit pixel, sufficient brightness to form a display device may be obtained.

Therefore, for example, in case of a rectangular pixel having a unit pixel size of 600 μm×300 μm (i.e., one side by the other side), a distance of a semiconductor light emitting element becomes sufficiently long relatively.

Thus, in this case, it is able to implement a flexible display device having high image quality over HD image quality.

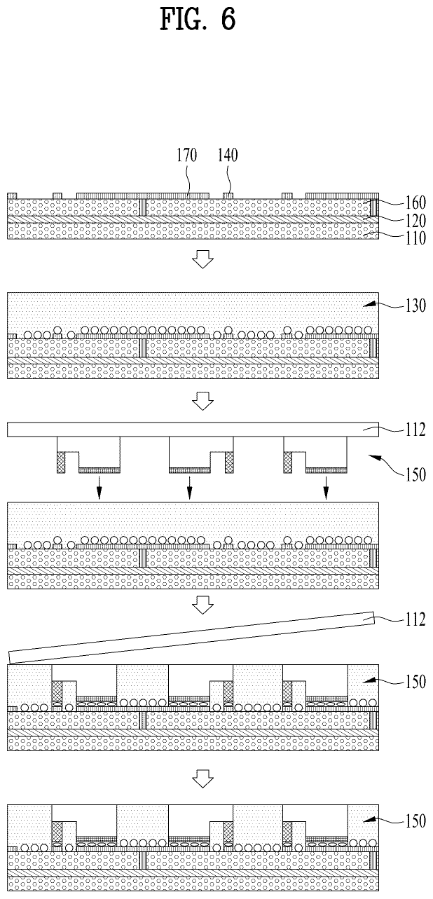

The above-described display device using the semiconductor light emitting element may be prepared by a new fabricating method. Such a fabricating method will be described with reference to FIG. 6 as follows.

FIG. 6 shows cross-sectional views of a method of fabricating a display device using a semiconductor light emitting element according to the present disclosure.

Referring to FIG. 6, first of all, a conductive adhesive layer 130 is formed on an insulating layer 160 located between an auxiliary electrode 170 and a second electrode 140. The insulating layer 160 is tacked on a wiring substrate 110. On the wiring substrate 110, a first electrode 120, the auxiliary electrode 170 and the second electrode 140 are disposed. In this case, the first electrode 120 and the second electrode 140 may be disposed in mutually orthogonal directions, respectively. In order to implement a flexible display device, the wiring substrate 110 and the insulating layer 160 may include glass or polyimide (PI) each.

For example, the conductive adhesive layer 130 may be implemented by an anisotropic conductive film. To this end, an anisotropic conductive film may be coated on the substrate on which the insulating layer 160 is located.

Subsequently, a temporary substrate 112, on which a plurality of semiconductor light emitting elements 150 configuring individual pixels are located to correspond to locations of the auxiliary electrode 170 and the second electrodes 140, is disposed in a manner that the semiconductor light emitting element 150 confronts the auxiliary electrode 170 and the second electrode 140.

In this regard, the temporary substrate 112 is a growing substrate for growing the semiconductor light emitting element 150 and may include a sapphire or silicon substrate.

The semiconductor light emitting element is configured to have a space and size for configuring a display device when formed in unit of wafer, thereby being effectively used for the display device.

Subsequently, the wiring substrate 110 and the temporary substrate 112 are thermally compressed together. By the thermocompression, the wiring substrate 110 and the temporary substrate 112 are bonded together. Owing to the property of an anisotropic conductive film having conductivity by thermocompression, only a portion among the semiconductor light emitting element 150, the auxiliary electrode 170 and the second electrode 140 has conductivity, via which the electrodes and the semiconductor light emitting element 150 may be connected electrically. In this case, the semiconductor light emitting element 150 is inserted into the anisotropic conductive film, by which a partition may be formed between the semiconductor light emitting elements 150.

Then the temporary substrate 112 is removed. For example, the temporary substrate 112 may be removed using Laser Lift-Off (LLO) or Chemical Lift-Off (CLO).

Finally, by removing the temporary substrate 112, the semiconductor light emitting elements 150 exposed externally. If necessary, the wiring substrate 110 to which the semiconductor light emitting elements 150 are coupled may be coated with silicon oxide (SiOx) or the like to form a transparent insulating layer (not shown).

In addition, a step of forming a phosphor layer on one side of the semiconductor light emitting element 150 may be further included. For example, the semiconductor light emitting element 150 may include a blue semiconductor light emitting element emitting Blue (B) light, and a red or green phosphor for converting the blue (B) light into a color of a unit pixel may form a layer on one side of the blue semiconductor light emitting element.

The above-described fabricating method or structure of the display device using the semiconductor light emitting element may be modified into various forms. For example, the above-described display device may employ a vertical semiconductor light emitting element.

Furthermore, a modification or embodiment described in the following may use the same or similar reference numbers for the same or similar configurations of the former example and the former description may apply thereto.

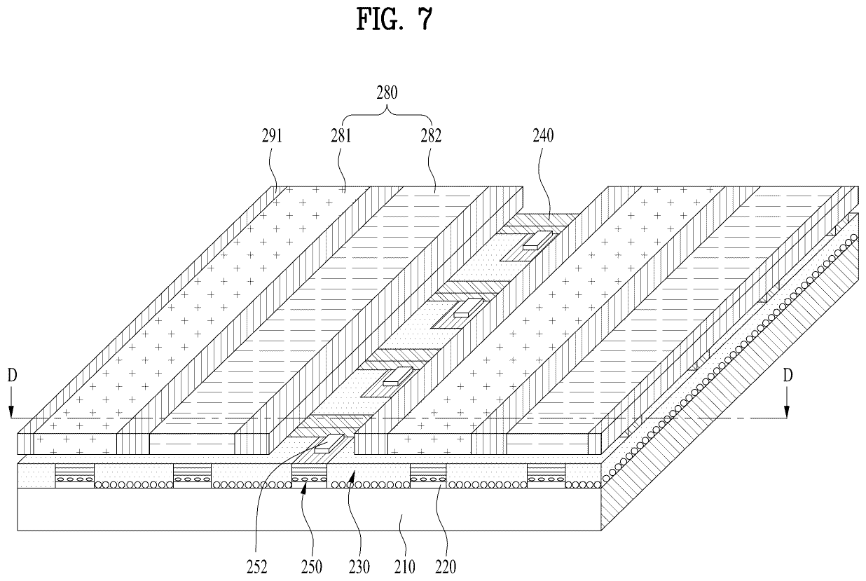

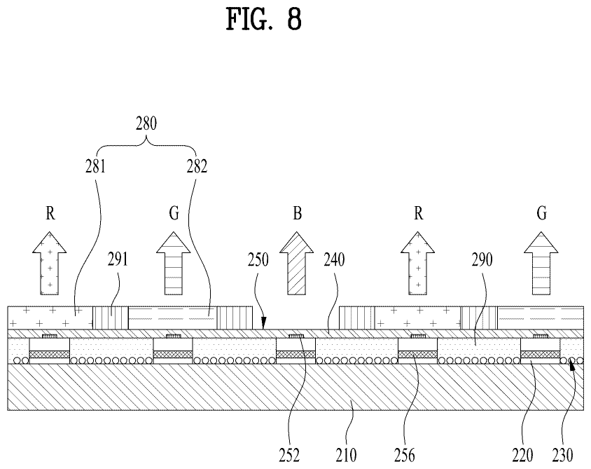

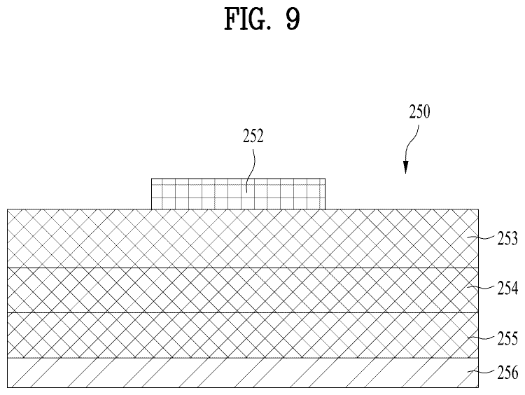

FIG. 7 is a perspective diagram of a display device using a semiconductor light emitting element according to another embodiment of the present disclosure, FIG. 8 is a cross-sectional diagram taken along a cutting line D-D shown in FIG. 8, and FIG. 9 is a conceptual diagram showing a vertical type semiconductor light emitting element shown in FIG. 8.

Referring to the present drawings, a display device may employ a vertical semiconductor light emitting device of a Passive Matrix (PM) type.

The display device includes a substrate 210, a first electrode 220, a conductive adhesive layer 230, a second electrode 240 and at least one semiconductor light emitting element 250.

The substrate 210 is a wiring substrate on which the first electrode 220 is disposed and may contain polyimide (PI) to implement a flexible display device. Besides, the substrate 210 may use any substance that is insulating and flexible.

The first electrode 210 is located on the substrate 210 and may be formed as a bar type electrode that is long in one direction. The first electrode 220 may be configured to play a role as a data electrode.

The conductive adhesive layer 230 is formed on the substrate 210 where the first electrode 220 is located. Like a display device to which a light emitting device of a flip chip type is applied, the conductive adhesive layer 230 may include one of an Anisotropic Conductive Film (ACF), an anisotropic conductive paste, a conductive particle contained solution and the like. Yet, in the present embodiment, a case of implementing the conductive adhesive layer 230 with the anisotropic conductive film is exemplified.

After the conductive adhesive layer has been placed in the state that the first electrode 220 is located on the substrate 210, if the semiconductor light emitting element 250 is connected by applying heat and pressure thereto, the semiconductor light emitting element 250 is electrically connected to the first electrode 220. In doing so, the semiconductor light emitting element 250 is preferably disposed to be located on the first electrode 220.

If heat and pressure is applied to an anisotropic conductive film, as described above, since the anisotropic conductive film has conductivity partially in a thickness direction, the electrical connection is established. Therefore, the anisotropic conductive film is partitioned into a conductive portion and a non-conductive portion.

Furthermore, since the anisotropic conductive film contains an adhesive component, the conductive adhesive layer 230 implements mechanical coupling between the semiconductor light emitting element 250 and the first electrode 220 as well as mechanical connection.

Thus, the semiconductor light emitting element 250 is located on the conductive adhesive layer 230, via which an individual pixel is configured in the display device. As the semiconductor light emitting element 250 has excellent luminance, an individual unit pixel may be configured in small size as well. Regarding a size of the individual semiconductor light emitting element 250, a length of one side may be equal to or smaller than 80 μm for example and the individual semiconductor light emitting element 250 may include a rectangular or square element. For example, the rectangular element may have a size equal to or smaller than 20 μm×80 μm.

The semiconductor light emitting element 250 may have a vertical structure.

Among the vertical type semiconductor light emitting elements, a plurality of second electrodes 240 respectively and electrically connected to the vertical type semiconductor light emitting elements 250 are located in a manner of being disposed in a direction crossing with a length direction of the first electrode 220.

Referring to FIG. 9, the vertical type semiconductor light emitting element 250 includes a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on then-type semiconductor layer 253. In this case, the p-type electrode 256 located on a bottom side may be electrically connected to the first electrode 220 by the conductive adhesive layer 230, and the n-type electrode 252 located on a top side may be electrically connected to a second electrode 240 described later. Since such a vertical type semiconductor light emitting element 250 can dispose the electrodes at top and bottom, it is considerably advantageous in reducing a chip size.

Referring to FIG. 8 again, a phosphor layer 280 may formed on one side of the semiconductor light emitting element 250. For example, the semiconductor light emitting element 250 may include a blue semiconductor light emitting element 251 emitting blue (B) light, and a phosphor layer 280 for converting the blue (B) light into a color of a unit pixel may be provided. In this regard, the phosphor layer 280 may include a red phosphor 281 and a green phosphor 282 configuring an individual pixel.

Namely, at a location of configuring a red unit pixel, the red phosphor 281 capable of converting blue light into red (R) light may be stacked on a blue semiconductor light emitting element. At a location of configuring a green unit pixel, the green phosphor 282 capable of converting blue light into green (G) light may be stacked on the blue semiconductor light emitting element. Moreover, the blue semiconductor light emitting element may be singly usable for a portion that configures a blue unit pixel. In this case, the unit pixels of red (R), green (G) and blue (B) may configure a single pixel.

Yet, the present disclosure is non-limited by the above description. In a display device to which a light emitting element of a flip chip type is applied, as described above, a different structure for implementing blue, red and green may be applicable.

Regarding the present embodiment again, the second electrode 240 is located between the semiconductor light emitting elements 250 and connected to the semiconductor light emitting elements electrically. For example, the semiconductor light emitting elements 250 are disposed in a plurality of columns, and the second electrode 240 may be located between the columns of the semiconductor light emitting elements 250.

Since a distance between the semiconductor light emitting elements 250 configuring the individual pixel is sufficiently long, the second electrode 240 may be located between the semiconductor light emitting elements 250.

The second electrode 240 may be formed as an electrode of a bar type that is long in one direction and disposed in a direction vertical to the first electrode.

In addition, the second electrode 240 and the semiconductor light emitting element 250 may be electrically connected to each other by a connecting electrode protruding from the second electrode 240. Particularly, the connecting electrode may include a n-type electrode of the semiconductor light emitting element 250. For example, the n-type electrode is formed as an ohmic electrode for ohmic contact, and the second electrode covers at least one portion of the ohmic electrode by printing or deposition. Thus, the second electrode 240 and the n-type electrode of the semiconductor light emitting element 250 may be electrically connected to each other.

Referring to FIG. 8 again, the second electrode 240 may be located on the conductive adhesive layer 230. In some cases, a transparent insulating layer (not shown) containing silicon oxide (SiOx) and the like may be formed on the substrate 210 having the semiconductor light emitting element 250 formed thereon. If the second electrode 240 is placed after the transparent insulating layer has been formed, the second electrode 240 is located on the transparent insulating layer. Alternatively, the second electrode 240 may be formed in a manner of being spaced apart from the conductive adhesive layer 230 or the transparent insulating layer.

If a transparent electrode of Indium Tin Oxide (ITO) or the like is sued to place the second electrode 240 on the semiconductor light emitting element 250, there is a problem that ITO substance has poor adhesiveness to an n-type semiconductor layer. Therefore, according to the present disclosure, as the second electrode 240 is placed between the semiconductor light emitting elements 250, it is advantageous in that a transparent electrode of ITO is not used. Thus, light extraction efficiency can be improved using a conductive substance having good adhesiveness to an n-type semiconductor layer as a horizontal electrode without restriction on transparent substance selection.

Referring to FIG. 8 again, a partition 290 may be located between the semiconductor light emitting elements 250. Namely, in order to isolate the semiconductor light emitting element 250 configuring the individual pixel, the partition 290 may be disposed between the vertical type semiconductor light emitting elements 250. In this case, the partition 290 may play a role in separating the individual unit pixels from each other and be formed with the conductive adhesive layer 230 as an integral part. For example, by inserting the semiconductor light emitting element 250 in an anisotropic conductive film, a base member of the anisotropic conductive film may form the partition.

In addition, if the base member of the anisotropic conductive film is black, the partition 290 may have reflective property as well as a contrast ratio may be increased, without a separate block insulator.

For another example, a reflective partition may be separately provided as the partition 290. The partition 290 may include a black or white insulator depending on the purpose of the display device.

In case that the second electrode 240 is located right onto the conductive adhesive layer 230 between the semiconductor light emitting elements 250, the partition 290 may be located between the vertical type semiconductor light emitting element 250 and the second electrode 240 each. Therefore, an individual unit pixel may be configured using the semiconductor light emitting element 250. Since a distance between the semiconductor light emitting elements 250 is sufficiently long, the second electrode 240 can be placed between the semiconductor light emitting elements 250. And, it may bring an effect of implementing a flexible display device having HD image quality.

In addition, as shown in FIG. 8, a black matrix 291 may be disposed between the respective phosphors for the contrast ratio improvement. Namely, the black matrix 291 may improve the contrast between light and shade.

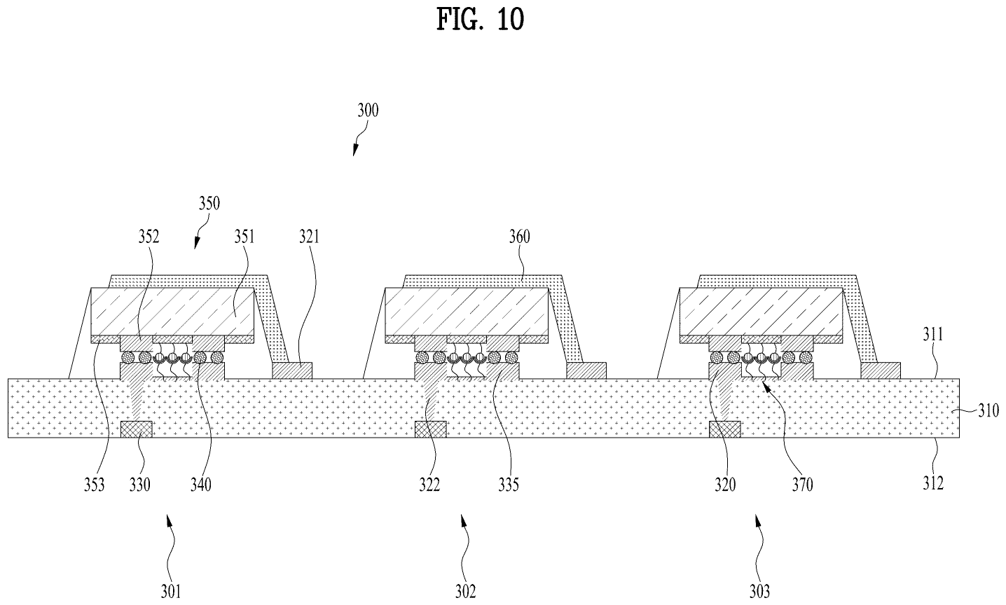

FIG. 10 is a schematic cross-sectional diagram illustrating a display apparatus using a light emitting device according to an embodiment of the present disclosure.

FIG. 10 illustrates an embodiment in which a vertical light emitting device 350 is used as an individual pixel (i.e., subpixel) of a display apparatus 300.

Referring to FIG. 10, a multitude of unit pixel areas 301, 302, and 303 may be defined on a substrate 310, and a pair of electrode pads 320 and 321 may be disposed in each of a multitude of the unit pixel areas 301, 302, and 303.

As described above, the substrate 310 may include a wiring substrate on which the electrode pads 320 and 321 and a wiring electrode 335 are disposed. Here, the wiring electrode 335 may include a portion of the electrode pads 320 and 321. In the state of FIG. 10, the wiring electrode 335 may not be clearly distinguished from the electrode pads 320 and 321. The wiring electrode 335 may be connected to each of the electrode pads 320 and 321 to be formed over the entire substrate 310. In other words, the electrode pads 320 and 321 may mean a portion of the wiring electrode 335 electrically connected to the light emitting device 350.

The light emitting device 350 may be installed in the electrode pads 320 and 321 located in each of the unit pixel areas 301, 302, and 303 to operate as a subpixel. As described above, the light emitting device 350 may be electrically connected to the wiring electrode 335 formed on the substrate 310.

Here, the light emitting device 350 may be a Light Emitting Diode (LED) described above. Specifically, the light emitting device 350 may include a micro LED. FIG. 10 illustrates an embodiment in which the vertical light emitting device 350 is used.

In the vertical light emitting device 350, a current may flow in a vertical direction of a semiconductor layer 351. For example, a current may flow from a first type electrode 352 provided to one side of the semiconductor layer 351 to a connection electrode 360 electrically connected to the other side of the semiconductor layer 351 in the vertical light emitting device 350.

The electrode pad provided to the substrate 310 may include a first electrode pad 320 formed on a first surface 311 of the substrate 310 and a second electrode pad 321 connected to the connection electrode 360.

A Thin Film Transistor (TFT) 330 capable of playing a switching role may be provided to a second surface 312 of the substrate 310.

In an exemplary embodiment, the first electrode pad 320 may be connected to the thin film transistor 330 through a through-electrode 322. The first electrode pad 320 may be electrically connected to the first type electrode 352 of the light emitting device 350. For example, the first electrode 352 of the light emitting device 350 may be electrically connected to the first electrode pad 320 by a conductive ball 340.

The electrical connection by the conductive ball 340 may be substantially the same as that of the conductive adhesive layer 130 described above. Therefore, a description of the electrical connection by the conductive ball 340 will be omitted.

The first type electrode 352 of the light emitting device 350 may have a donut shape. The first electrode pad 320 corresponding thereto may also have a donut shape. The first electrode pad 320 electrically connected to the thin film transistor 330 may be connected to a pixel electrode (a data electrode, a lighting electrode).

The other side of the first type electrode 352 of the light emitting device 350 may be in electrical contact with the connection electrode 360. For example, a separate electrode may not be formed on the other side of the first type electrode 352. The connection electrode 360 may be connected to the second electrode pad 321.

In this case, the light emitting device 350 and the unit device area 301/302/303 partitioned on the first surface 311 of the substrate 310 may be bonded together by a bonding formation part 370. The bonding formation part 370 may provide a bonding strength by which the light emitting device 350 is assembled to the unit device area 301/302/303. The magnitude of the bonding strength may be smaller than the bonding strength of the conductive adhesive layer 130.

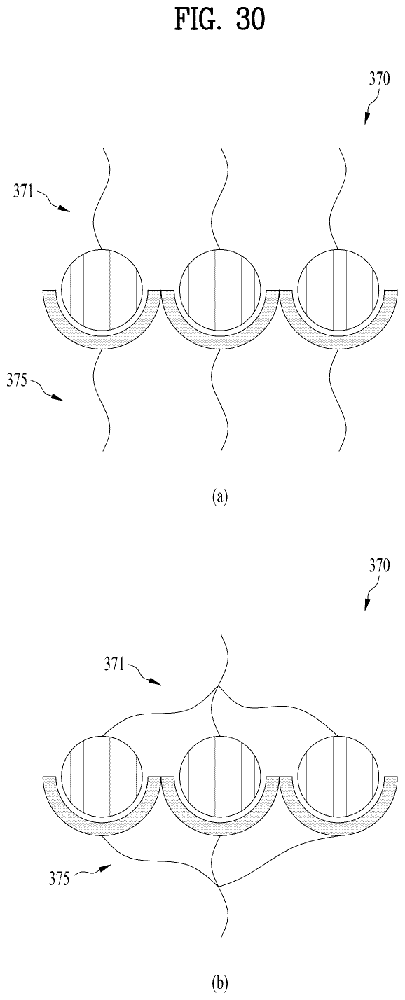

The bonding formation part 370 may include an active part 371 (e.g. see FIG. 30) bonded to the light emitting device 350 and a bonding part 375 (e.g. see FIG. 30) patterned on the substrate 310 to be chemically bonded to the active part 371 (FIG. 30 schematically shows that the active part 371 and the bonding part 375 are chemically bonded together, which will be described in detail below.).

For example, the light emitting device 350 may be primarily assembled to the unit device area 301/302/303 partitioned on the first surface 311 of the substrate 310 by the bonding strength provided by the bonding formation part 370, and then the light emitting device 350 may be electrically connected to the first electrode pad 320 by the conductive ball 340.

In this case, as illustrated, the bonding formation part 370 may be positioned inside the donut shape.

As described above, the light emitting device 350 may form a chemical bond with the substrate 310 by the coupling forming unit 370, thereby being aligned and assembled at a desired position. The chemical bonding provided by the bonding formation part 370 may provide the position selectivity of the light emitting device 350, and at the same time, may provide the bonding strength that enables the light emitting device 350 to be bonded until being electrically connected and permanently fixed.

For example, when the light emitting device 350 is assembled to unit device area 301/302/303 of the substrate in the fluid, it is possible to prevent the assembled light emitting device 350 from being separated by the fluid flow.

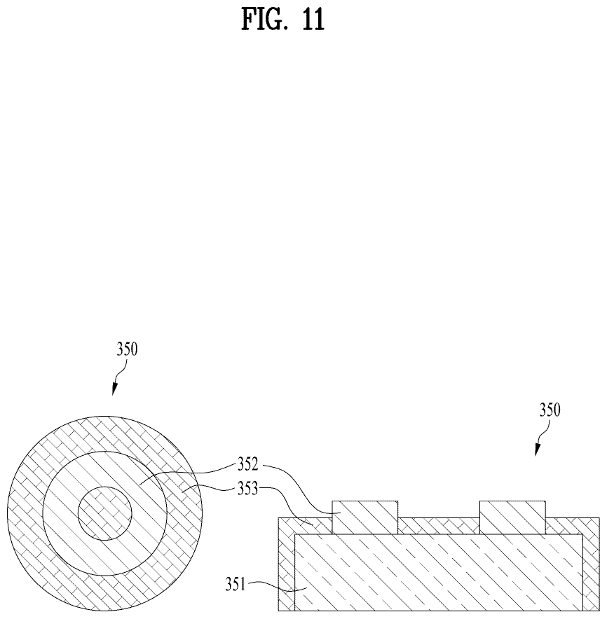

FIG. 11 is a diagram illustrating an example of a vertical light emitting device usable in a display apparatus using a light emitting device according to an embodiment of the present disclosure.

FIG. 11 (a) is a layout of a vertical light emitting device 350, and FIG. 11 (b) is a cross-sectional diagram of the vertical light emitting device 350.

Referring to FIG. 11 (a), the vertical light emitting device 350 having the donut-shaped first electrode 352 described above with reference to FIG. 10 is shown. A first type electrode 352 may be formed on one surface of a semiconductor layer 351, and the one surface failing to have the first type electrode 352 formed thereon and a side surface of the semiconductor layer 351 may be protected by a passivation layer 353. Here, the semiconductor layer 351 may include a gallium nitride (GaN)-based semiconductor.

Although the passivation layer 353 may be disposed on a surface opposite to the surface having the first type electrode 352 of the vertical light emitting device 350 formed thereon, it may be removed for electrical connection later to form a state as shown in FIG. 11 (b).

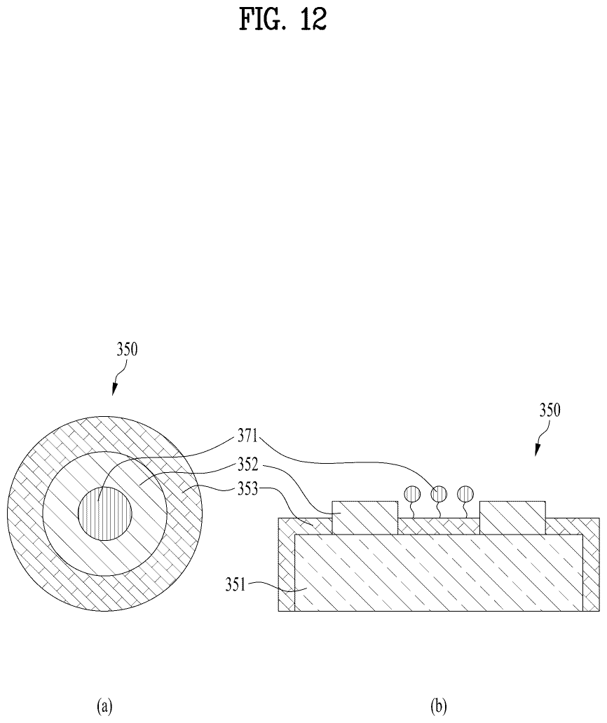

FIG. 12 is a diagram illustrating a state in which an active part is introduced into the vertical light emitting device of FIG. 11.

An active part 371 may be introduced to a mounting surface (i.e., the upper surface in FIG. 12) of the vertical light emitting device 350. As an example embodiment, as mentioned above, the active part 371 may be introduced inside the first type electrode 352. That is, the active part 371 may be located inside the donut-shaped first type electrode 352.

Yet, the active part 371 may be introduced to the entire mounting surface of the light emitting device 350. In this case, the first type electrode 352 may be temporarily masked.

As an exemplary embodiment, in order to fabricate the light emitting device 350, a wafer on which the GaN-based semiconductor layer 351 is formed may be etched into individual chips, and a passivation layer 353 may be formed on the semiconductor layer 351.

Thereafter, when photo patterning for depositing a first type electrode 352 is performed, a portion of the passivation layer 353 for forming an active part may be left in the center of the light emitting device 350. The corresponding portion may be surface-treated so that the active part 371 may be bonded through plasma treatment or the like after the donut-shaped first type electrode 352 is formed.

As described above, a structure of the light emitting device 350 having the active part 371, as shown in FIG. 12, may be formed by introducing the active part 371 capable of molecular recognition bonding such as host-guest interaction, antigen-antibody interaction, or the like on the surface-treated light emitting device 350 through chemical vapor deposition or polymer condensation reaction.

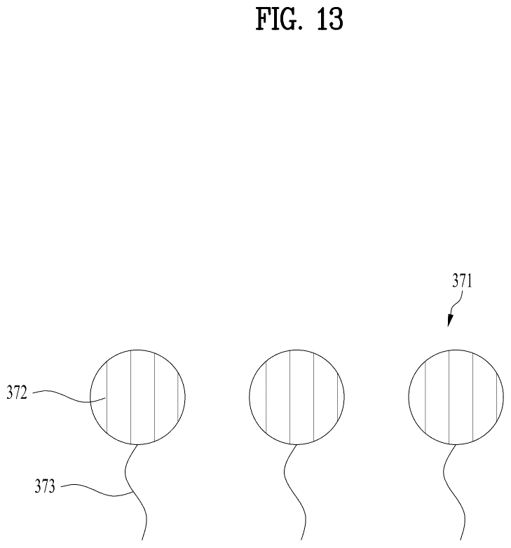

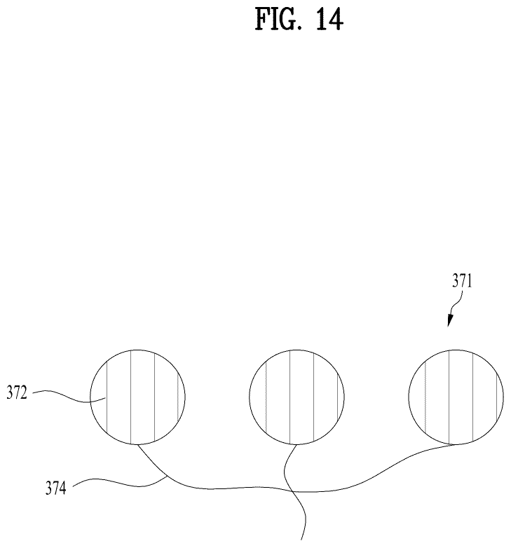

FIG. 13 is a schematic diagram illustrating one example of an active part usable in a display apparatus using a light emitting device according to an embodiment of the present disclosure. FIG. 14 is a schematic diagram illustrating another example of an active part usable in a display apparatus using a light emitting device according to an embodiment of the present disclosure.

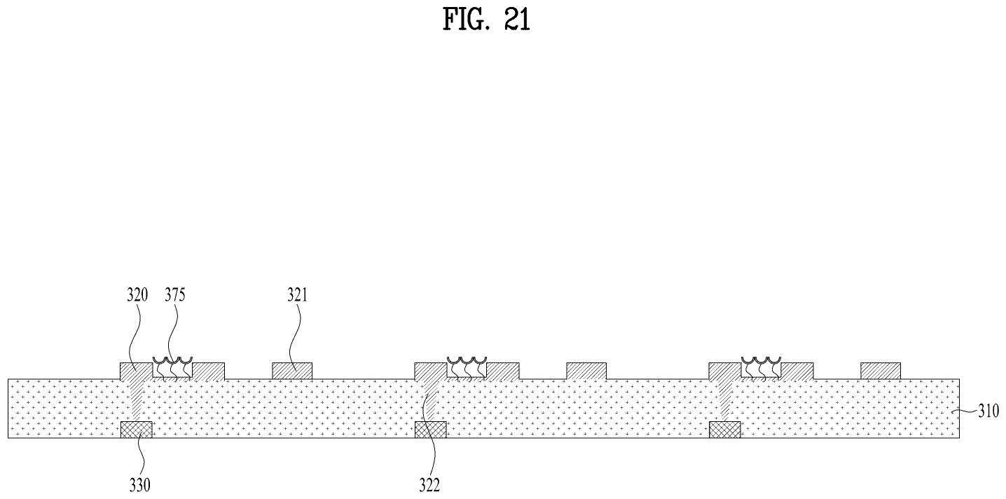

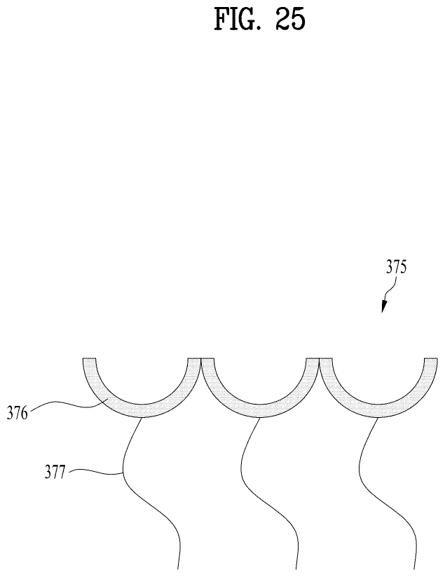

Referring to FIG. 13 and FIG. 14, an active part 371 introduced to a mounting surface of a light emitting device 350 may include a first compound 372 capable of providing a chemical bonding strength. Substantially, such a first compound 372 may be bonded with a bonding part 375 (see FIG. 21). The bonding part 375 may include a second compound 376 (see FIG. 25) bonded to the first compound 372.

The first compound 372 and the second compound 376 may be bonded together by molecular recognition bonding including host-guest interaction or antigen-antibody interaction. That is, the first compound 372 may be subjected to molecular recognition bonding (e.g., host-guest interaction, antigen-antibody interaction, etc.) with the second compound 376. This will be described in detail below.

The first compound 372 may include at least one of a guest material or an antigen material including one of an aromatic compound and a monosaccharide compound.

As a specific example, the first compound 372 may include an aromatic compound such as Adamantane, Azobenzene, Pythelian, etc., a gust material of a monosaccharide compound such as Glucose, etc., or an antigen such as Mannose, Biotin, etc.

A thickness of the first compound 372 may be one to two times that of the first type electrode 352, and an area of the first compound 372 may be set to be 0.1 to 0.3 time the first type electrode 352. Accordingly, the first compound 372 may not disturb the electrical connection with the first electrode pad 320.

In addition, the first compound 372 may be bonded to the light emitting device 350 by a polymer chain structure 373/374.

In an exemplary embodiment, the bond length of the polymer chain structure 373/374 may be adjusted according to external conditions. For example, the polymer chain structure 373/374 may include at least one of a temperature-sensitive polymer or a photosensitive functional group. In other words, the bond length of the polymer chain structure 373/374 may be adjusted according to a temperature or a pH. The polymer chain structures 373 and 374 will be described in detail later.

Referring to FIG. 13, a basic structure in which the first compound 372 is connected to an end of the polymer chain structure 373 bonded to an upper portion of the light emitting device 350 is shown.

The polymer chain structure 373 may be formed of a material capable of maintaining a long chain shape without agglomeration in a fluid where the light emitting device 350 is assembled to the substrate 310. For example, if the used fluid is water, at least one of ethylene glycol-based, propylene glycol-based, siloxane-based, acrylic, and urethane-based polymers having a hydrophilic functional group may be used.

Referring to FIG. 14, the polymer chain structure 374 in the form of a dendrimer may be used to enable multivalent interaction for the density increase of the first compound 372 and the bonding strength enhancement between the first compound 372 and the paired material in the active part 371. In this case, monomers such as ethylene glycol, propylene glycol, propylene imine, and the like may be used.

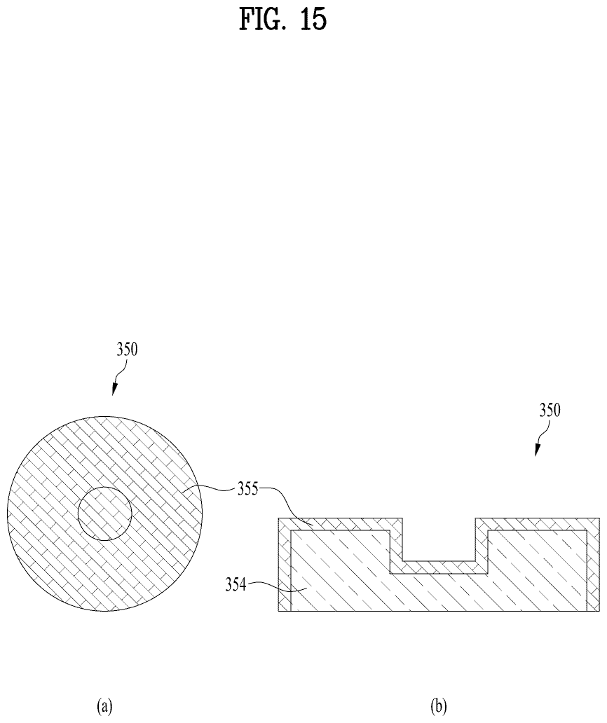

FIG. 15 is a diagram illustrating an example of a horizontal light emitting device usable in a display apparatus using a light emitting device according to an embodiment of the present disclosure.

FIG. 15 (a) is a layout of a horizontal light emitting device 350, and FIG. 15 (b) is a cross-sectional diagram of the horizontal light emitting device 350.

Referring to FIG. 15 (a), a donut-shaped horizontal light emitting device 350 is shown. In the horizontal light emitting device 350, an upper surface and a side surface of a semiconductor layer 354 may be protected by a passivation layer 355. Here, the semiconductor layer 354 may include a gallium nitride (GaN)-based semiconductor.

Although the passivation layer 355 may be disposed on a lower surface of the horizontal light emitting device 350, it may be removed for electrical connection later to form a state as shown in FIG. 15 (b).

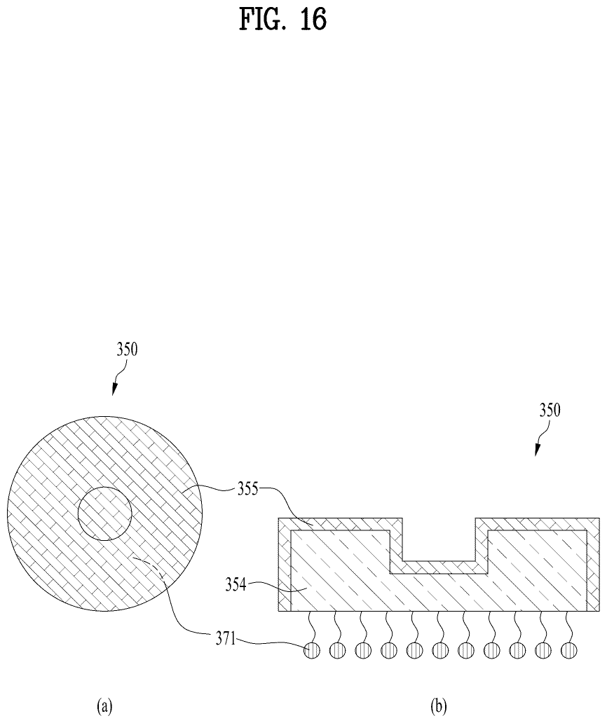

FIG. 16 is a diagram illustrating a state in which an active part is introduced into the horizontal light emitting device of FIG. 15.

An active part 371 may be introduced to a mounting surface (lower surface in FIG. 16) of a horizontal light emitting device 350. As an exemplary embodiment, as mentioned above, the active part 371 may be introduced to a lower surface where the semiconductor layer 354 is exposed. For example, the active part 371 may be entirely or partially located on the lower surface of the horizontal light emitting device 350.

As an exemplary embodiment, after a wafer having the GaN-based semiconductor layer 354 is etched into an individual chip and a passivation layer 355 is formed thereon, the semiconductor layer 354 may be transferred to a temporary substrate.

The semiconductor layer 354 may be transferred to the temporary substrate through a method such as laser lift-off, mechanical lift-off, chemical lift-off, etc. and a lower portion of the semiconductor layer 354 may be surface-treated through plasma treatment or the like for formation of the active part 371 so as to have a compound bonded thereto.

A first compound 372 capable of molecular recognition bonding such as host-guest interaction, antigen-antibody interaction, or the like is introduced under the surface-treated light emitting device 350 again through chemical vapor deposition or polymer condensation reaction to form a structure of the light emitting device 350 having the active part 371 in a form as shown in FIG. 16.

As described with reference to FIG. 12, the first compound 372 may use an aromatic compound such as Adamantane, Azobenzene, Pytrene, a guest material of a monosaccharide compound such as Glucose or the like, or an antigen such as Mannose or biotin.

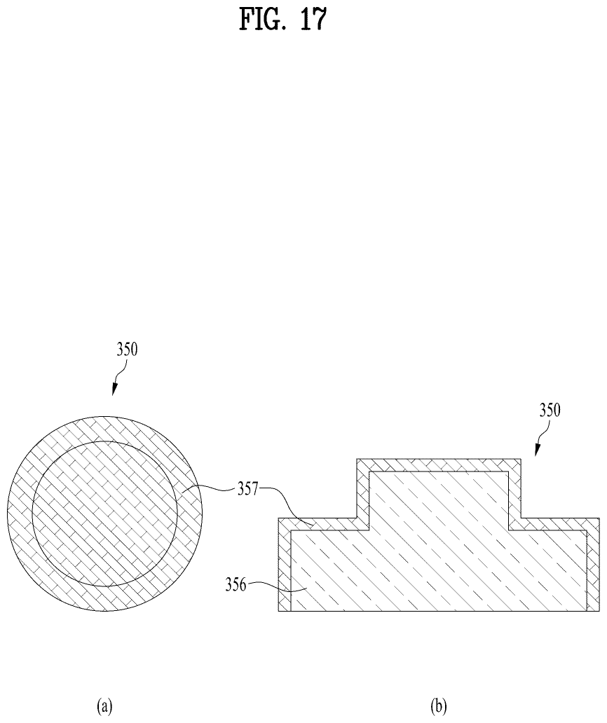

FIG. 17 is a diagram illustrating another example of a horizontal light emitting device usable in a display apparatus using a light emitting device according to an embodiment of the present disclosure.

FIG. 17 (a) is a layout of a horizontal light emitting device 350, and FIG. 17 (b) is a cross-sectional diagram of the horizontal light emitting device 350.

Referring to FIG. 17 (a), a hat-shaped horizontal light emitting device 350 is shown. In the horizontal light emitting device 350, an upper surface and a side surface of the semiconductor layer 356 may be protected by a passivation layer 357. Here, the semiconductor layer 356 may include a gallium nitride (GaN)-based semiconductor.

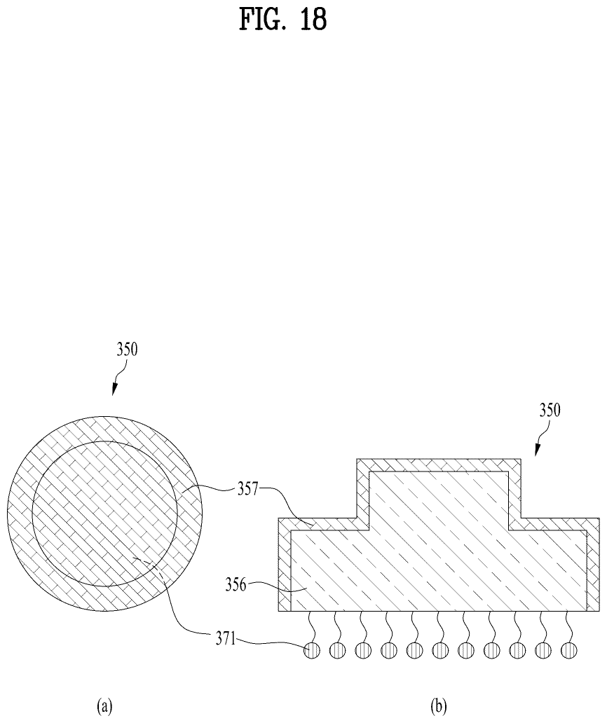

FIG. 18 is a diagram illustrating a state in which an active part is introduced into the horizontal light emitting device of FIG. 17.

An active part 371 may be introduced to a mounting surface (lower surface in FIG. 18) of the horizontal light emitting device 350. As an example embodiment, as mentioned above, the active part 371 may be introduced to a lower surface where the semiconductor layer 356 is exposed. For example, the active part 371 may be entirely or partially located on the lower surface of the horizontal light emitting device 350.

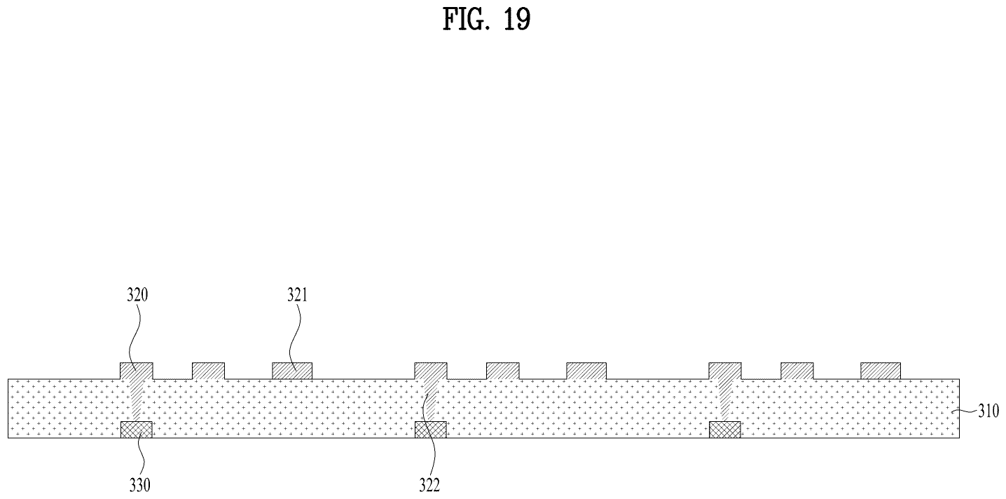

FIGS. 19 to 21 are diagrams illustrating a process of fabricating a display apparatus using a light emitting device according to a first embodiment of the present disclosure.

FIGS. 19 to 21 illustrate a process of fabricating a display apparatus using the vertical light emitting device 350 described with reference to FIG. 11 and FIG. 12 systematically.

FIG. 19 schematically illustrates a cross-section of a wiring substrate 310 on which electrode pads 320 and 321 connected to a wiring, to which the vertical light emitting device 350 is assembled, are formed.

On the wiring substrate 310, a first electrode pad 320 electrically connected to a first type electrode 352 and a thin film transistor 330 of the vertical light emitting device 350 and a second electrode pad 321 usable as a common electrode may be formed.

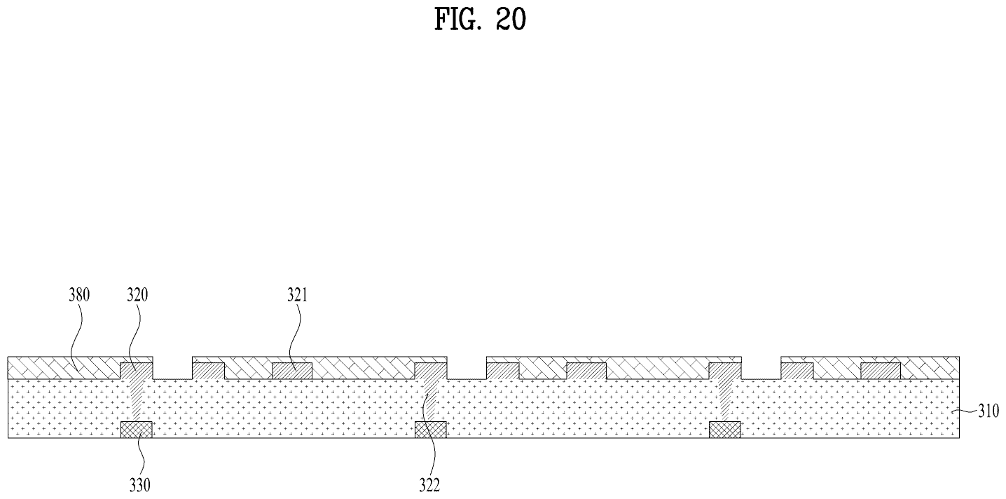

Referring to FIG. 20, a photoresist 380 may be formed on the wiring substrate 310 excluding a portion where ac bonding part 375 is to be formed through a photo patterning process that may be generally used for fabricating the wiring substrate 310. That is, an upper surface of the wiring substrate 310 excluding the portion where the bonding part 375 is to be formed may be covered with the photoresist 380.

In the state that the photoresist 380 is formed, the bonding part 375 including a second compound 376 may be coated on the entire wiring substrate 310. By this process, the bonding part 375 may be formed on a predetermined portion on the wiring substrate 310.

That is, the bonding part 375 that may be chemically bonded to the active part 371 introduced into the light emitting device 350 may be patterned on the wiring substrate 310.

In doing so, the bonding part 375 patterned on the wiring substrate 310 may include a functional group capable of chemically bonding with the surface of the wiring substrate 310. In this case, the bonding part 375 may be strongly connected to the wiring substrate 310 through a chemical reaction.

Thereafter, when the photoresist 380 is removed, the remaining bonding part 375 and the second compound 376 may also be removed. Accordingly, as shown in FIG. 21, the wiring substrate 310 on which the bonding part 375 for assembling the light emitting device 350 thereto is patterned may be obtained.

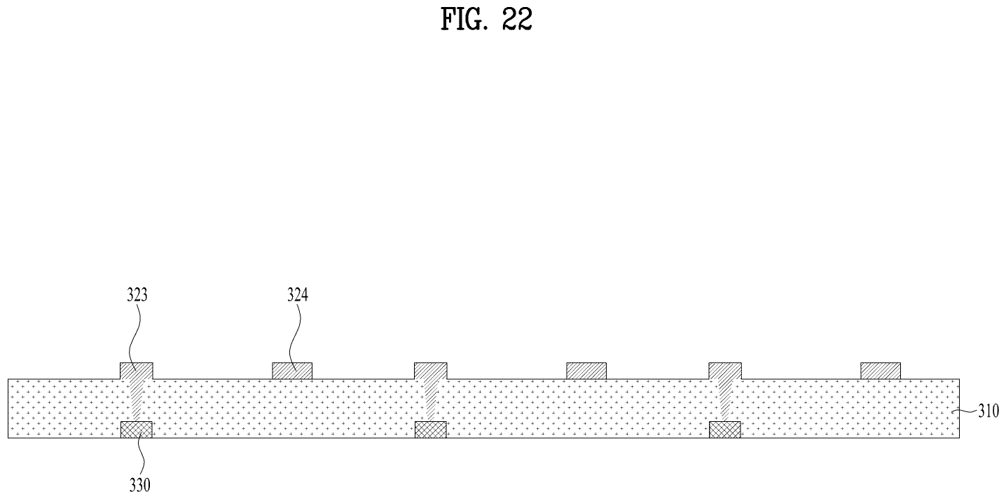

FIGS. 22 to 24 are diagrams illustrating a process of fabricating a display apparatus using a light emitting device according to a second embodiment of the present disclosure.

FIGS. 22 to 24 illustrate a process of fabricating a display apparatus using the horizontal light emitting device 350 described with reference to FIGS. 15 to 18.

FIG. 22 schematically illustrates a cross-section of a wiring substrate 310 on which electrode pads 323 and 324 connected to a wiring, to which the horizontal light emitting device 350 is assembled, are formed.

The two electrode pads 323 and 324 may be electrically connected to two electrodes of the horizontal light emitting device 350, respectively. For example, the two electrode pads 323 and 324 may be connected to a first type electrode (e.g. a p-type electrode) and a second type electrode (e.g. an n-type electrode) located on the same surface of the horizontal light emitting device 350, respectively.

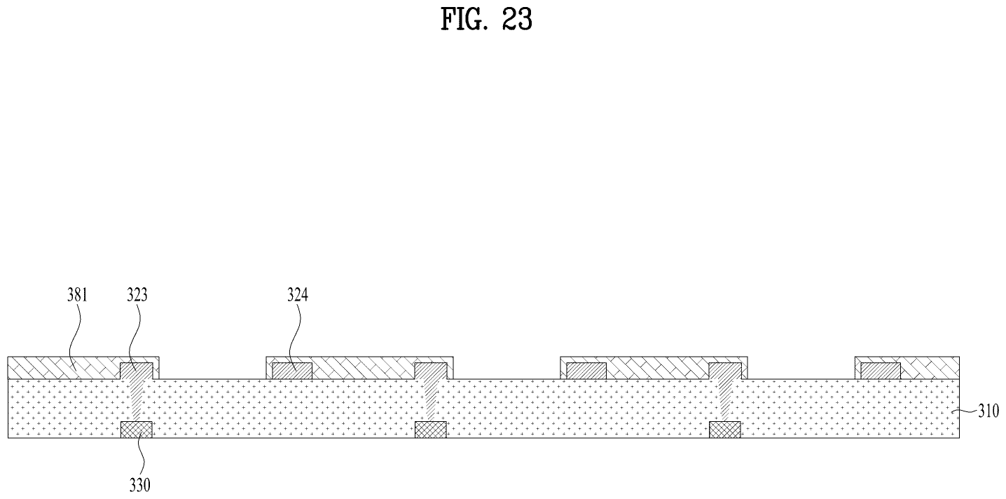

Referring to FIG. 23, a photoresist 381 may be formed on a portion excluding a portion where the bonding part 375 is to be formed through a photo patterning process generally usable for fabricating the wiring substrate 310. That is, an upper surface of the wiring substrate 310 excluding the portion where the bonding part 375 is to be formed may be covered with the photoresist 381.

In a state that the photoresist 381 is formed, the bonding part 375 including a second compound 376 may be coated on the entire wiring substrate 310. By this process, the bonding part 375 may be formed on a predetermined portion on the wiring substrate 310.

Like the wiring substrate 310 for assembling the vertical light emitting device described above, the bonding part 375 patterned on the wiring substrate 310 may include a functional group capable of chemically bonding with the surface of the wiring substrate 310. In this case, the bonding part 375 may be strongly connected to the wiring substrate 310 through a chemical reaction.

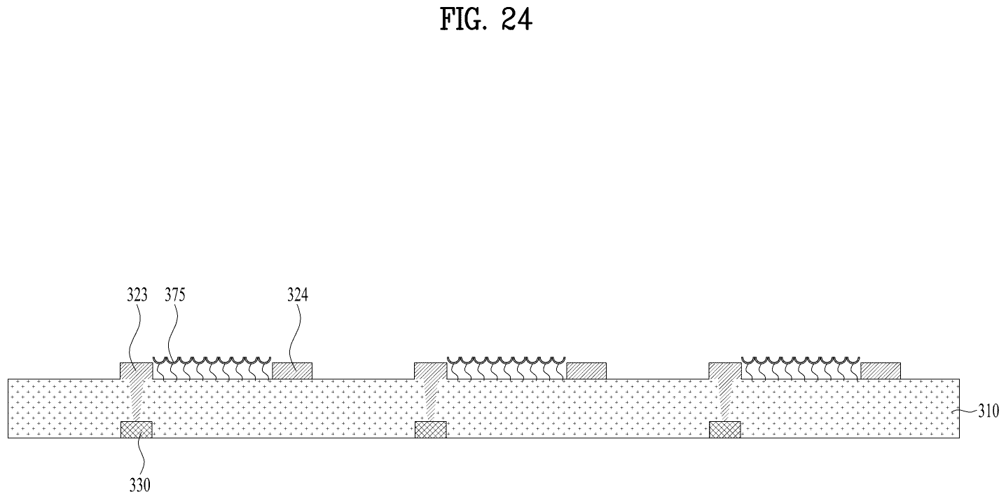

Thereafter, when the photoresist 381 is removed, the remaining bonding part 375 and the second compound 376 may also be removed. Therefore, as shown in FIG. 24, the wiring substrate 310 on which the bonding part 375, to which the horizontal light emitting device 350 is to be assembled, may be obtained.

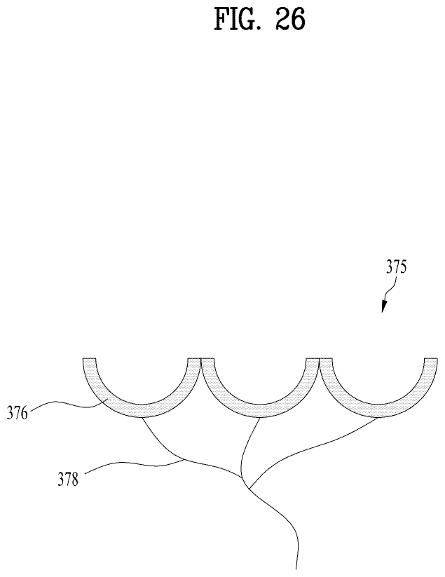

FIG. 25 is a schematic diagram illustrating an example of a bonding part usable in a display apparatus using a light emitting device according to an embodiment of the present disclosure. FIG. 26 is a schematic diagram illustrating another example of a bonding part usable in a display apparatus using a light emitting device according to an embodiment of the present disclosure.

Referring to FIG. 25 and FIG. 26, a bonding part 375 introduced to a mounting surface of a wiring substrate 310 may include a second compound 376 capable of providing a chemical bonding strength. Substantially, such a second compound 376 may be bonded with an active part 371.

The first compound 372 and the second compound 376 may be bonded by a molecular recognition bonding including a host-guest interaction or an antigen-antibody interaction. That is, the second compound 376 may perform molecular recognition bonding such as host-guest interaction, antigen-antibody interaction, and the like with the first compound 371. This will be described in detail below.

The second compound 376 may include at least one of a host material, which is a macrocyclic compound, or an antibody material capable of bonding to an antigen material, as a functional group capable of pairing with the first compound 372.

As a specific example, there is a basic structure in which the second compound 376 is connected to the end of a polymer chain structure 377/378 connected to the bonding part 375 patterned on the wiring substrate 310.

The second compound 376 may use a host material, which is a macrocyclic compound represented by cyclodextrin, cucurbituril, and calixarene, or an antibody material such as Concanavalin A, Streptavidin, etc., as a functional group capable of being bonded by being paired with the first compound 372.

In addition, the second compound 376 may be bonded to the wiring substrate 310 by the polymer chain structure 377/378.

In an exemplary embodiment, the bond length of each of the polymer chain structures 377 and 378 may be adjusted according to external conditions. For example, each of the polymer chain structures 377 and 378 may include at least one of a temperature-sensitive polymer or a pH-sensitive functional group. In other words, the bond length of each of the polymer chain structures 377 and 378 may be adjusted according to a temperature or a pH. The polymer chain structures 377 and 378 will be described in detail later.

Referring to FIG. 25, shown is a basic structure in which the second compound 376 is connected to the end of the polymer chain structure 377 bonded to the upper surface of the wiring substrate 310.

The polymer chain structure 376 may be formed of a material capable of maintaining a long chain shape without agglomeration in a fluid for assembling the light emitting device 350 to the substrate 310. For example, if the used fluid is water, at least one of ethylene glycol-based, propylene glycol-based, siloxane-based, acrylic, and urethane-based polymers having a hydrophilic functional group may be used.

Referring to FIG. 26, the polymer chain structure 378 in the form of a dendrimer may be used to enable multivalent interaction for the density increase of the second compound 376 and the reinforcement of the coherence with the pairing material in the bonding part 375. In this case, monomers such as ethylene glycol, propylene glycol, propylene imine, and the like may be used.

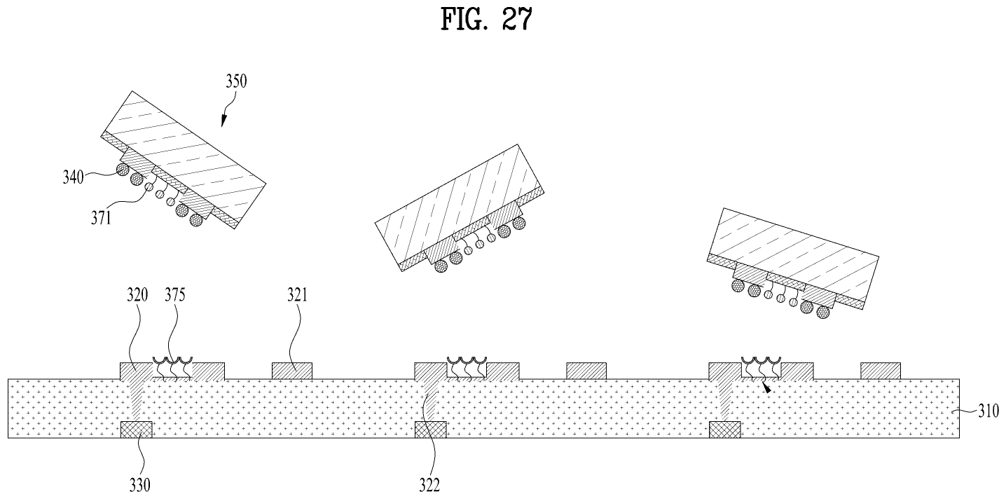

FIGS. 27 to 32 are diagrams illustrating an assembly process of a vertical light emitting device in a display apparatus using a light emitting device according to an embodiment of the present disclosure.

Referring to FIGS. 27 to 32, shown is an example in which a light emitting device 350 is assembled in a unit pixel area through chemical bonding between an active part 371 of the vertical light emitting device 350 and a bonding part 375 of a wiring substrate 310.

As mentioned above, assembly of the light emitting device 350 may be performed in a fluid. The fluid may be contained in a water tank (not shown). The wiring substrate 310 is placed in the fluid in the water tank, and the light emitting device 350 may be assembled in a unit device area of the wiring substrate 310 while flowing in the fluid.

FIG. 27 shows a state in which the vertical light emitting device 350 flows in the fluid while the wiring substrate 310 is placed in the fluid.

A conductive ball 340 may be placed on a first type electrode of the vertical light emitting device 350 to secure electrical connection with the wiring substrate 310. At least one of a nickel ball, a polymer ball, a solder ball, and the like may be used as the conductive ball 340. As described above, the conductive adhesive layer 130 may be used as the conductive ball 340.

As described above, when the light emitting device 350 to which an active part 371 is attached is flowed in the fluid in a state in which the wiring substrate 310 is positioned in the water tank containing the fluid, the light emitting device 350 moves in various directions along the flow of the fluid.

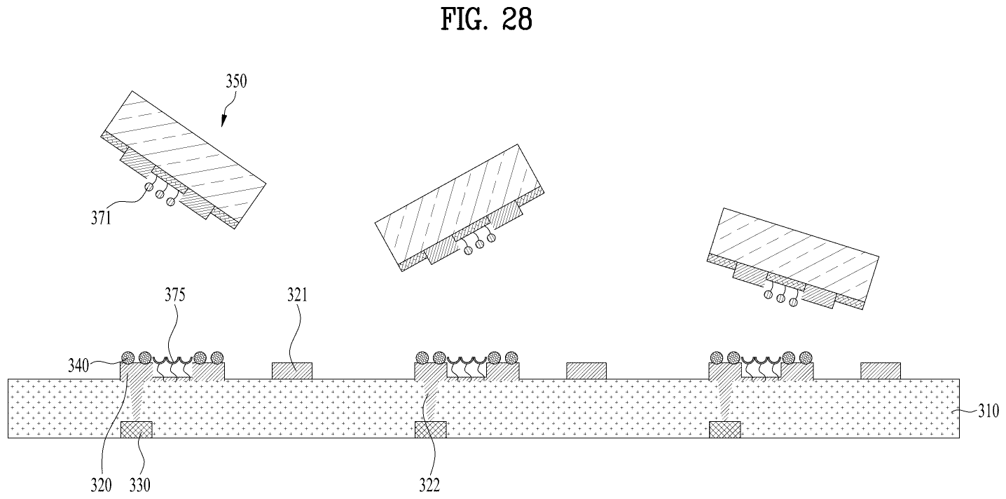

Meanwhile, as shown in FIG. 28, the conductive ball 340 may be disposed on a first electrode pad 320 instead of the vertical light emitting device 350.

Thereafter, when the active part 371 of the vertical light emitting device 350 approaches the bonding part 375 patterned on the wiring substrate 310, a chemical non-covalent bond is formed between a first compound 372 of the active part 371 and a second compound 376 of the bonding part 375. By this process, the vertical light emitting device 350 may be assembled in the unit device area on the wiring substrate 310, that is, the first electrode pad 320.

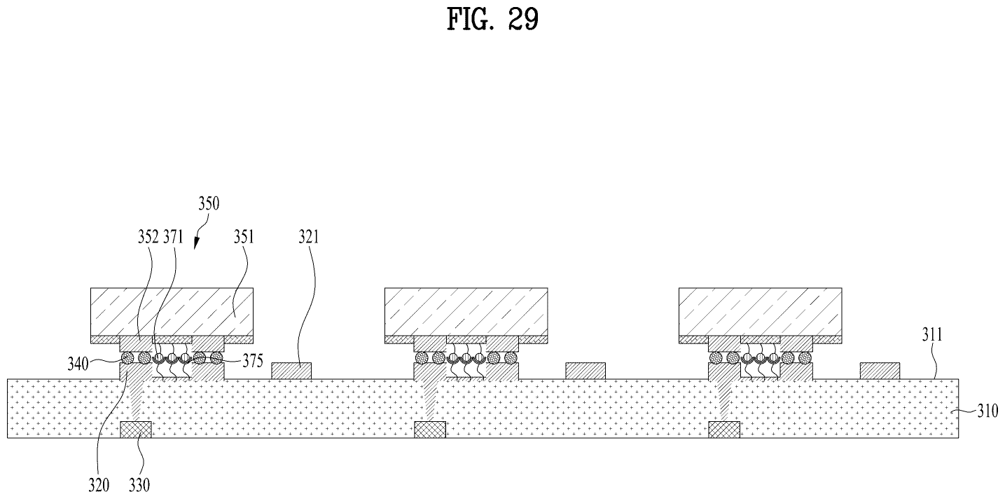

Referring to FIG. 29, in a state in which the active part 371 forms the chemical non-covalent bond with the bonding part 375, a first type electrode 352 of the vertical light emitting device 350 may contact the first electrode pad 320 of the wiring substrate 310.

Thus, owing to the chemical bonding between the bonding part 375 and the active part 371, that is, the chemical non-covalent bonding between the first compound 372 of the active part 371 and the second compound 376 of the bonding part 375, the vertical light emitting device 350 may be bonded to the wiring board 310 to maintain the bonded state. Accordingly, the vertical light emitting element 350 may be stably assembled without being separated from the wiring board 310 again by being swept along the flow of the fluid.

FIG. 30 illustrates a state in which the active part 371 and the bonding part 375 described above form the non-covalent bond. That is, FIG. 30 illustrates an example of a bonding formation part 370.

FIG. 30 (a) illustrates a state in which the basic structure having the polymer chain structure 373 bonded to the first compound 372 of the active part 371 is bonded to the basic structure having the polymer chain structure 377 bonded to the second compound 376, as an example of the bonding formation part 370.

FIG. 30 (b) illustrates a state in which the structure having the dendrimer type polymer chain structure 374 bonded to the first compound 372 of the active part 371 to enable the multivalent interaction is bonded to the structure having the dendrimer type polymer chain structure 377 bonded to the second compound 376 to enable the multivalent interaction.

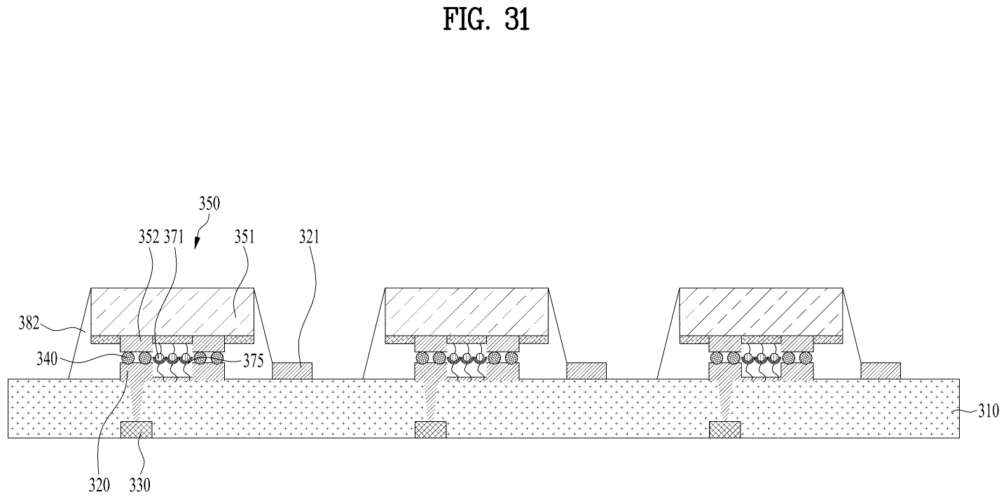

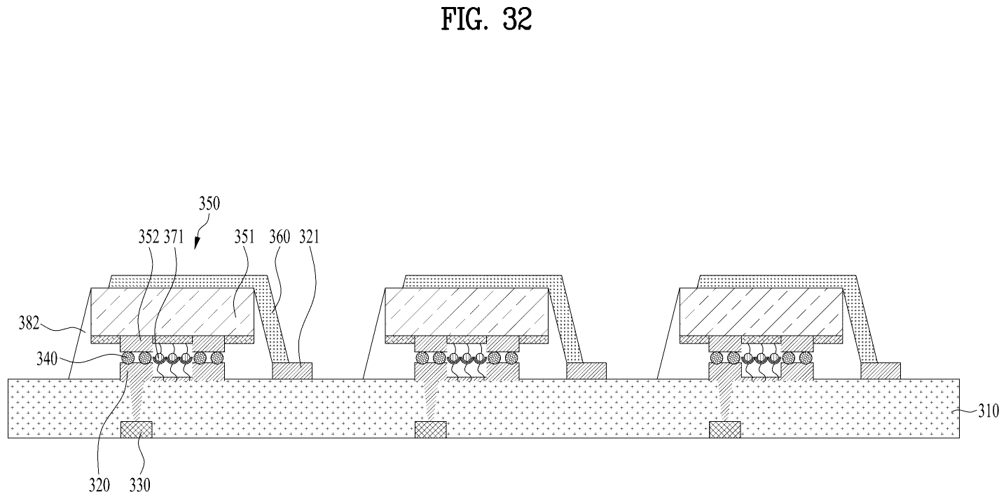

FIG. 31 and FIG. 32 illustrate an example of an electrical connection process for the lighting of an assembled vertical light emitting device 350.

Referring to FIG. 31, an adhesive material 382 may be printed to secure reliability on an environment of an electrical connection between an assembled vertical light emitting device 350 and a wiring substrate 310. The adhesive material 382 may be applied to a peripheral side of a first type electrode 352 of the vertical light emitting device 350 and a peripheral side of a first electrode pad 320 of the wiring substrate 310, in which an active part 371 and a bonding part 375 are bonded together.

The adhesive material 382 may use an epoxy-based, acrylic-based, or silicon-based resin. Screen printing, inkjet printing, gravure printing, or the like may be used as the printing method of the adhesive material 382.

Thereafter, the light emitting device 350 may be bonded to the wiring substrate 310 using a press at room or high temperature.

Referring to FIG. 32, a second electrode pad 321 of the wiring substrate 310 may be connected to an opposite surface of the first type electrode 352 of the vertical light emitting device 350 by a connection electrode 360. By this process, the vertical light emitting device 350 may enter a lighting-enabled state. Thereafter, the bonded state between the active part 371 and the bonding part 375 may be maintained.

The connection electrode 360 may be deposited and patterned using a transparent electrode material. As the transparent electrode material, Indium Tin Oxide (ITO), metal mesh, Ag nanowire, graphene, or the like may be used.

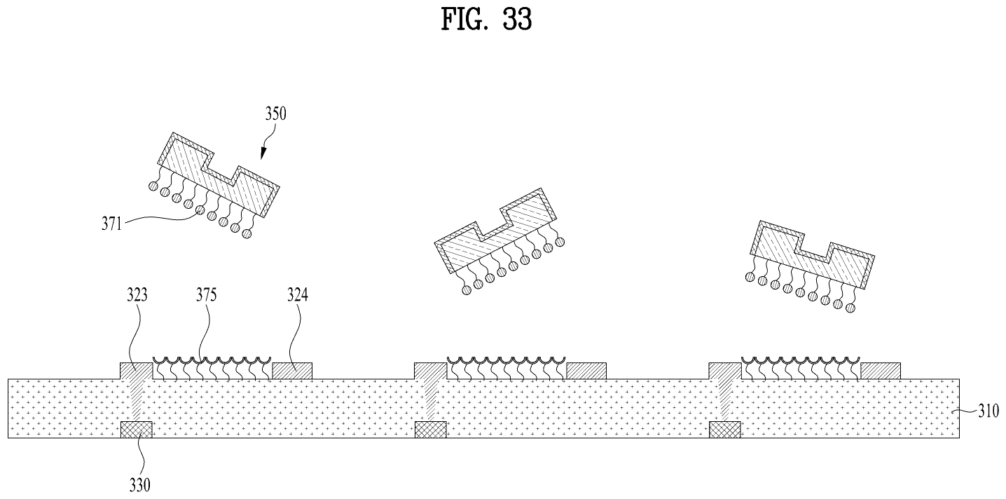

FIGS. 33 to 36 are diagrams illustrating an assembly process of a horizontal light emitting device in a display apparatus using a light emitting device according to an embodiment of the present disclosure.

Referring to FIGS. 33 to 36, shown is an example in which a light emitting device 350 is assembled in a unit pixel area through chemical bonding between an active part 371 of the horizontal light emitting device 350 and a bonding part 375 of a wiring substrate 310.

As mentioned above, assembly of the light emitting device 350 may be performed in a fluid. The fluid may be contained in a water tank (not shown). The wiring substrate 310 may be placed in the fluid in the water tank and the horizontal light emitting device 350 may be assembled in a unit device area of the wiring substrate 310 while flowing in the fluid.

FIG. 33 shows a state in which the wiring substrate 310 is placed in the fluid and the donut-shaped horizontal light emitting device 350 is flowing in the fluid.

Thus, when the horizontal light emitting device 350 to which the active part 371 described above is attached is flowed in the fluid in a state that the wiring substrate 310 is positioned in the water tank containing the fluid, the light emitting device 350 moves in various directions along the flow of the fluid.

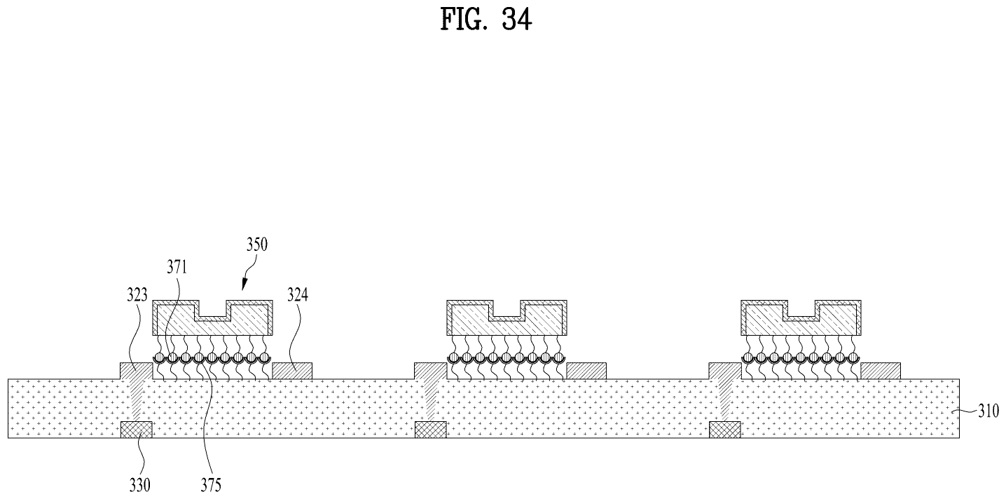

Thereafter, when the active part 371 of the horizontal light emitting device 350 approaches the bonding part 375 patterned on the wiring substrate 310, a chemical non-covalent bond is formed between a first compound 372 of the active part 371 and a second compound 376 of the bonding part 375, as shown in FIG. 34. By this process, the vertical light emitting device 350 may be bonded in a unit device area on the wiring substrate 310, i.e., between two electrode pads 323 and 324.

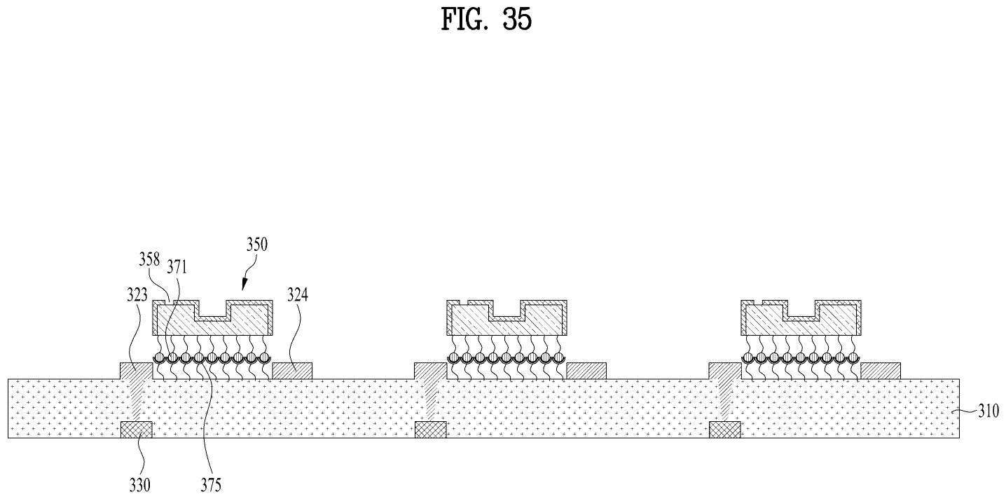

Referring to FIG. 35, a portion of a passivation layer 355 may be etched to provide a connection portion 358 of a first type electrode (e.g., a p-type electrode) and a second type electrode (e.g., an n-type electrode) on the assembled light emitting device 350.

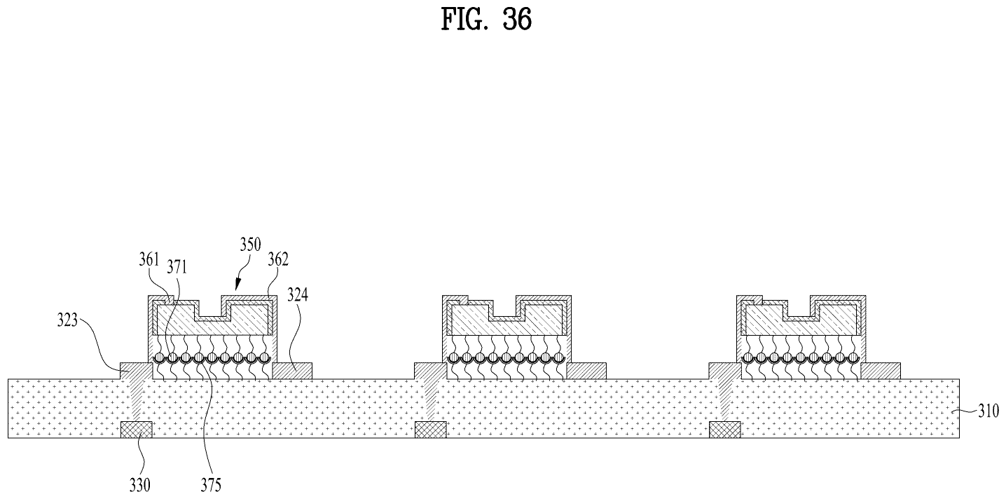

Thereafter, as shown in FIG. 36, connection wirings 361 and 362 may be formed to connect the first type electrode (e.g., the p-type electrode) and the second type electrode (e.g. the n-type electrode) located on the same surface of the horizontal light emitting device 350 to the two electrode pads 323 and 324, respectively.

By this process, the horizontal light emitting device 350 may enter a lighting-enabled state. Thereafter, the bonded state between the active part 371 and the bonding part 375 may be maintained.

The connection wirings 361 and 362 may be deposited and patterned using a transparent electrode material. As the transparent electrode material, Indium Tin Oxide (ITO), metal mesh, Ag nanowire, graphene, or the like may be used.

Thus, the horizontal light emitting device 350 may be bonded to the wiring substrate 310 to maintain the coupling state by chemical bonding between the active part 371 and the bonding part 375, i.e., the chemical non-covalent bonding between the first compound 372 of the active part 371 and the second compound 376 of the bonding part 375.

Although a process of assembling the doughnut-shaped horizontal light emitting device 350 has been described, this may be equally applied to the cap-shaped light emitting device 350 described above with reference to FIG. 17 and FIG. 18.

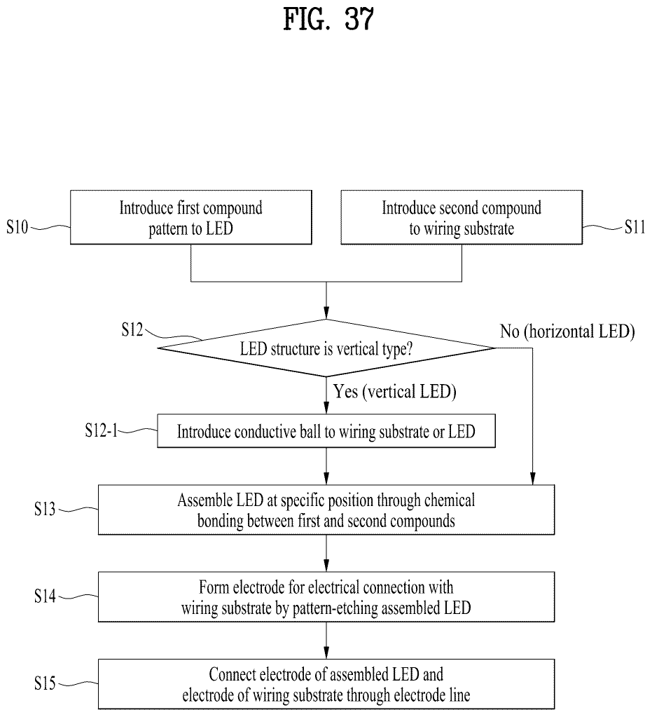

FIG. 37 is a flowchart illustrating a method of fabricating a display apparatus using a light emitting device according to an embodiment of the present disclosure.

Referring to FIG. 37, the assembly process of the vertical light emitting device 350 described with reference to FIGS. 27 to 32 and the assembly process of the horizontal light emitting device 350 described with reference to FIGS. 33 to 36 are summarized and shown together.

First, a first compound 372 (or an active part 371 including the first compound 372) may be introduced into a light emitting device 350 (S10). In addition, a second compound 376 (or a bonding part 375 including a second compound 376) may be introduced into a wiring substrate 310 (S11). The two steps S10 and S11 may be independently performed.

Thus, the steps S10 and S11 of introducing a bonding formation part 370 for assembling the light emitting device 350 to a unit device area on the wiring substrate 310 using chemical bonding may be performed.

Thereafter, if the light emitting device 350 has a vertical structure (S12), a conductive ball 340 may be introduced (S12-1). For example, the conductive ball 340 may be introduced into the wiring substrate 310 or the light emitting device 350.

If the light emitting device 350 has a horizontal structure, the step of introducing the conductive ball 340 may be omitted and a subsequent assembly step (S13) may be entered.

In the assembly step S13, the light emitting device 350 may be assembled to a specific position (e.g., a unit device area) through a chemical bond between the first compound 372 and the second compound 376. That is, as described above, the step S13 of assembling the light emitting device 350 to the unit device area by using the bonding strength by the bonding formation part 370 on the fluid may be performed.

Thereafter, steps S14 and S15 of electrically connecting the assembled light emitting device 350 to the wiring (electrode pad) of the wiring substrate 310 may be performed.

First, the assembled light emitting device 350 may be pattern-etched to form a contact (electrode) for electrical connection (contact) with the wiring substrate 310. For example, a portion of a passivation layer 355 may be etched to prepare a contact portion 358.

Thereafter, the contact (electrode) of the assembled light emitting device 350 and the electrode pad of the wiring substrate 310 may be connected to each other through an electrode line. For example, a connection electrode 360 may be connected to a second electrode pad 321 or may be connected to the electrode pad 323/324 using a connection wiring 361/362.

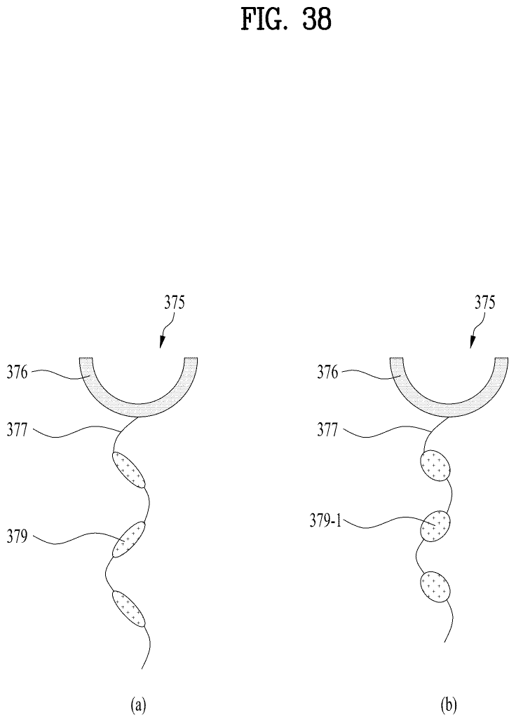

FIG. 38 is a conceptual diagram illustrating a specific example of a polymer chain structure used in a display apparatus using a light emitting device according to an embodiment of the present disclosure.

FIG. 38 shows an example of sensitive polymers 379 and 379-1 applicable to a polymer chain structure 377 used in a bonding part 375.

The length of the sensitive polymer 379/379-1 may be adjusted by an external stimulus. The sensitive polymer 379/379-1 may form a part of the polymer chain structure 377. That is, the sensitive polymer 379/379-1 may be included in the polymer chain structure 377.

Although the sensitive polymers 379 and 379-1 applied to the bonding part 375 are illustrated in FIG. 38, the sensitive polymers 379 and 379-1 may be equally used in an active part 371 as well.

The sensitive polymers 379 and 379-1 may be added to the polymer chain structure 377. FIG. 38 (a) shows a state before the length is reduced, and FIG. 38 (b) shows a state after the length is reduced.

The polymer chain structure 377 may be adjusted according to external conditions by applying the sensitive polymer 379/379-1.

In an exemplary embodiment, the polymer chain structure 377 may include at least one of a temperature-sensitive polymer or a pH-sensitive functional group.

As a specific example, the polymer chain structure 377 may include a dendrimer type polymer chain structure or a monomer including at least one of ethylene glycol, propylene glycol, and propylene imine.

For example, each of the sensitive polymers 379 and 379-1 applied to the polymer chain structure 377 may include a temperature-sensitive polymer such as poly(N-isopropylacrylamide), poly(2-(diethylamino) ethyl methacrylate), poly(methyl vinyl ether), etc., which are reduced in length according to an increase in a predetermined temperature in water, or at least one of pH-sensitive functional groups such carboxylic acids, sulfonic acids, phosphonic acids, dextran, etc., which are reduced in length according to a pH change.

The sensitive polymer 379/379-1 applied to the polymer chain structure 377 causes the polymer chain structures 377 to be agglomerated while the fluid molecules in the vicinity of the sensitive polymer 379/379-1 are discharged when an external stimulus (e.g., temperature, pH) occurs, thereby reducing a total chain length and volume. Through this effect, after the first compound 372 and the second compound 376 are bonded to each other, the light emitting device 350 may be more stably assembled in a manner of being withdrawn closer in the direction of the wiring substrate 310.

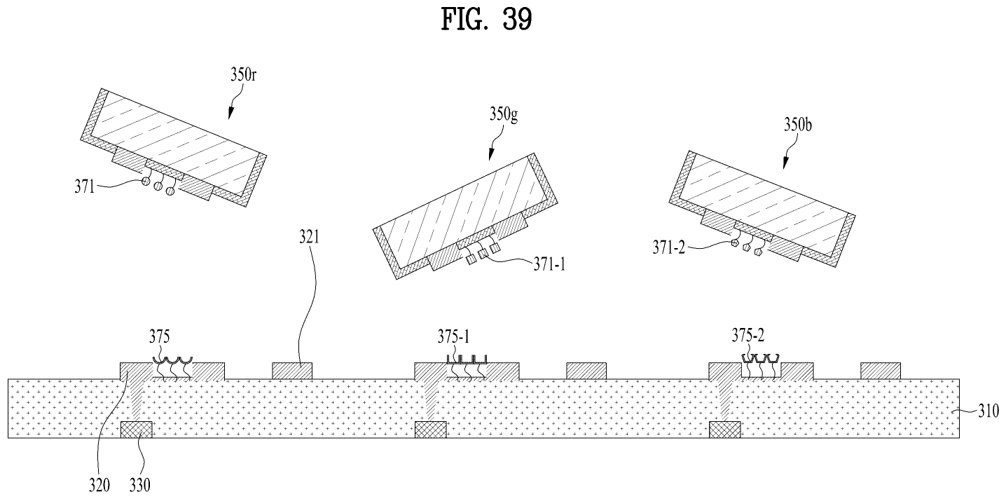

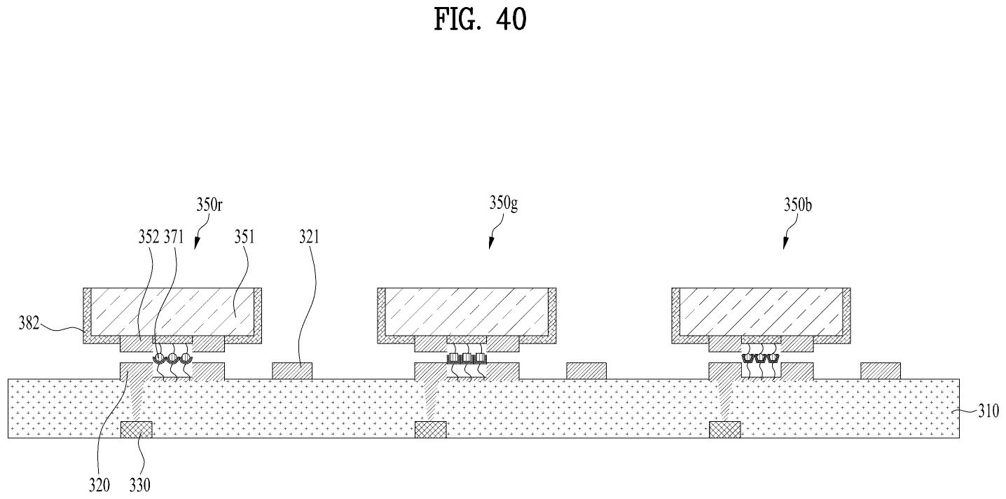

FIG. 39 and FIG. 40 are diagrams illustrating a state of having selectivity for each color of a pixel in a display apparatus using a light emitting device according to an embodiment of the present disclosure.

FIG. 39 and FIG. 40 show a state of having selectivity for each color of a pixel when the vertical light emitting device 350 described with reference to FIGS. 27 to 30 is assembled. That is, by applying different compounds to the light emitting devices 350 assembled to the red, green, and blue pixel areas and the corresponding unit pixel areas, it may be possible to assemble pixels for each color.

As described above, a red light emitting device 350r, a green light emitting device 350g, and a blue light emitting device 350b may be selectively assembled to red, green, and blue pixels, respectively.

In an exemplary embodiment, the red light emitting device 350r, the green light emitting device 350g, and the blue light emitting device 350b may include compounds capable of recognizing different molecules so as to be assembled at predetermined pixel positions, respectively, i.e., so as not to be assembled at other pixel positions, respectively.

For example, among the compounds described above, Adamantane 371 may be used as a first compound used for the active part 371 for the red light emitting device 350r, Glucose 371-1 may be used as the first compound 371 for the green light emitting device 350g, and Biotin 371-2 may be used for the blue light emitting device 350b, thereby introducing compounds having different pairs, respectively.

Similarly, the bonding parts 375 of the wiring substrate 310 may be patterned with compounds paired with the respective light emitting devices 350r, 350g, and 350b so that the light emitting devices of different colors, that is, the red light emitting device 350r, the green light emitting device 350r, and the blue light emitting device 350b may be assembled at desired positions, respectively.

For example, in a position at which the red light emitting device 350r is assembled, Cyclodextrin 375 may be used as the second compound 376 used for the bonding part 375 that may be bonded to the first compound (or the active part 371), and Calixarene 375-1 capable of being bonded with the first compound 371-1 may be used at a position where the green light emitting device 350g is assembled, and Sreptavidin 375-2 capable of being bonded with the first compound 371-2 may be used at a position where the blue light emitting device 350b is assembled (here, for convenience of description, the active part and the first compound are interchangeably used and the bonding part and the second compound are interchangeably described as well).

Thereafter, as shown in FIG. 40, when the active parts 371, 371-1, and 371-2 of the light emitting devices 350r, 350g, and 350b approach the bonding parts 375, 375-1, and 375-2 of the wiring substrate 310, the active parts 371, 371-1, and 371-2 may be bonded to the bonding parts 375, 375-1, and 375-2 to form chemical non-covalent bonds, respectively, and the light emitting devices 350r, 350g, and 350b may be assembled at the corresponding positions on the wiring substrate 310, respectively.

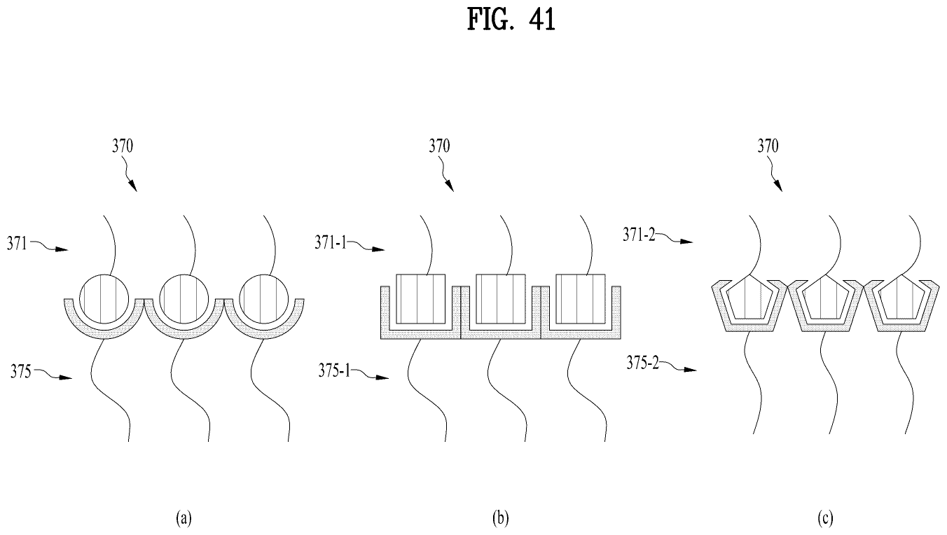

FIG. 41 is a conceptual diagram illustrating an example in which a different bonding formation part is formed for each color of a light emitting device.

FIG. 41 (a) illustrates an example of a bonding formation part 370 forming a pair of an active part 371 and a bonding part 375. For example, the bonding formation part 370 that forms the pair may be used for assembly of a red light emitting device 350r.

FIG. 41 (b) illustrates an example of a bonding formation part 370 forming a pair of an active part 371-1 and a bonding part 375-1. For example, the bonding formation part 370 forming the pair may be used for assembly of a green light emitting device 350g.

FIG. 41 (c) illustrates an example of a bonding formation part 370 forming a pair of an active part 371-2 and a bonding part 375-2. For example, the bonding formation parts 370 forming the pair may be used for assembly of a blue light emitting device 350b.

As described above, by applying different pairs of the active parts 371, 371-1 and 371-2 and the bonding parts 375, 375-1, and 375-2 for colors of pixels, the light emitting devices 350r, 350g, and 350b may be simultaneously assembled to the pixels of colors, respectively.

In fabricating a display apparatus using a micro LED, a light emitting device and a wiring substrate for driving may be fabricated in different processes and may not be compatible with each other, so that a transfer process and an electrical connection process may be essentially required.

In particular, various methods for quickly and accurately transferring a multitude of light emitting devices to a large area have been reviewed, but it is difficult to implement a stable process without a large number of defects.

However, the assembly structure of the light emitting device implemented in the present disclosure described above may provide a light source in a completed form of a light emitting device chip for stable and efficient fluid assembly by adding a simple process step without changing an existing light emitting device chip process.

A shape of the light emitting device chip provided in this form may reduce a defect assembly probability such as double assembly, detachment after assembly, etc., which may become an issue in a fluid assembly system. In addition, since a light emitting device chip adjacent to a designated position is easily assembled, a complicated series of processes for precisely adjusting a size and frequency of an electric field for dispersing and moving the light emitting device can be omitted, thereby improving productivity.

When the present disclosure is used, the light emitting device is assembled to the wiring substrate based on chemical bonding, thereby increasing assembly stability. In addition, when the light emitting device and the wiring substrate are introduced by distinguishing the compounds to be paired, the light emitting device may be position-selectively transferred.

The features, structures, effects, and the like described in the above embodiments are included in at least one embodiment of the present disclosure, and are not necessarily limited to one embodiment. Furthermore, the features, structures, effects, and the like illustrated in each embodiment may be combined or modified for other embodiments by those skilled in the art to which the embodiments pertain. Therefore, the contents related to the combination and modification should be construed as falling within the scope of the present disclosure.

In addition, although the embodiments have been described above, the present disclosure is merely an example and the present disclosure is not limited thereto. Various modifications and applications, which are not illustrated in the present embodiment, may be possible without departing from the essential characteristics of the present embodiment. For example, each component specifically shown in the embodiment may be modified and implemented. Further, differences related to such modifications and applications should be construed as being included in the scope of the present disclosure defined in the appended claims.

### INDUSTRIAL APPLICABILITY

According to the present disclosure, a display apparatus using a semiconductor light emitting device such as a micro LED and a fabricating method thereof may be provided.

What is claimed is:

1. A display apparatus, comprising:
a substrate having a multitude of unit pixel areas defined thereon;
a wiring electrode located in each of the unit pixel areas on the substrate;
a light emitting device assembled in each of the unit pixel areas by electrically connecting a device electrode to the wiring electrode; and
a bonding formation part providing a bonding strength for bonding the light emitting device to the unit pixel area, the coupling forming portion comprising:
an active part bonded to the light emitting device; and
a bonding part chemically bonded to the active part and patterned on the substrate.

2. The display apparatus of claim 1, wherein the active part comprises a first compound and wherein the bonding part comprises a second compound bonded to the first compound.

3. The display apparatus of claim 2, wherein at least one of the first compound or the second compound is bonded to the light emitting device or the substrate by a polymer chain structure.

4. The display apparatus of claim 3, wherein a bond length of the polymer chain structure is adjusted according to an external condition.

5. The display apparatus according to claim 3, wherein the polymer chain structure comprises at least one of a temperature-sensitive polymer or a pH-sensitive functional group.

6. The display apparatus of claim 3, wherein the polymer chain structure comprises a dendrimer type polymer chain structure or a monomer including at least one of ethylene glycol, propylene glycol, or propylene imine.

7. The display apparatus of claim 2, wherein the first compound and the second compound are bonded by molecular recognition bonding including a host-guest interaction or an antigen-antibody interaction.

8. The display apparatus of claim 7, wherein the first compound comprises at least one of a guest material including one of an aromatic compound and a monosaccharide compound or an antigen material.

9. The display apparatus of claim 8, wherein the second compound comprises a host material of a macrocyclic compound or an antibody material capable of bonding to the antigen material as a functional group capable of bonding by forming a pair with the first compound.

10. The display apparatus of claim 1, wherein the bonding formation part comprises a different compound according to a color of a pixel of the unit pixel area.

11. The display apparatus of claim 1, wherein the wiring electrode comprises a metal pad in a donut shape and wherein the bonding part is located inside the donut shape.

12. A method of fabricating a display apparatus using a light emitting device, the method comprising:
introducing a bonding formation part for assembling the light emitting device to a unit device area on a wiring substrate based on a chemical bonding;
assembling the light emitting device to the unit device area based on a bonding strength by the bonding formation part in a fluid; and
electrically connecting the light emitting device to a wiring of the wiring substrate.

13. The method of claim 12, the introducing the bonding formation part comprising:
introducing a first compound to the light emitting device; and
introducing a second compound to the unit device area.

14. The method of claim 13, wherein the first compound and the second compound are bonded by a molecular recognition bonding including a host-guest interaction or an antigen-antibody interaction.

15. The method of claim 14, wherein the first compound comprises at least one of a guest material including one of an aromatic compound and a monosaccharide compound or an antigen material.

16. The method of claim 15, wherein the second compound comprises a host material of a macrocyclic compound or an antibody material capable of bonding to the antigen material as a functional group capable of bonding by forming a pair with the first compound.

17. The method of claim 13, wherein at least one of the first compound or the second compound is bonded to the light emitting device or the substrate by a polymer chain structure.

18. The method of claim 17, wherein the polymer chain structure comprises at least one of a temperature-sensitive polymer or a pH-sensitive functional group.

19. The method of claim 17, wherein the polymer chain structure comprises a dendrimer type polymer chain structure or a monomer including at least one of ethylene glycol, propylene glycol, or propylene imine.

20. The method of claim 12, wherein the assembling the light emitting device to the unit device area comprises reducing a bond length of the bonding formation part.
